(19) United States
(12) Patent Application Publication
(10) Pub. No.: US 2026/0247614 A1
(43) Pub. Date: Aug. 20, 2026

(54) MEMORY DEVICE AND MANUFACTURING METHOD THEREOF

(71) Applicant: MACRONIX INTERNATIONAL CO., LTD., HSINCHU (TW)

(72) Inventor: YAN-RU SU, Chiayi County (TW)

(21) Appl. No.: 19/058,145

(22) Filed: Feb. 20, 2025

(51) Int. Cl. H10B 43/27; H10B 43/30

(52) U.S. Cl. CPC H10B 43/27; H10B 43/30

(57) ABSTRACT

A memory device includes a substrate, a stacked structure, first slits and second slits. The substrate has a memory array region and a staircase region. The stacked structure includes a first gate stacked structure and second gate stacked structures. The first gate stacked structure is located over the memory array region, and the second gate stacked structures are located over the staircase region. The first and the second gate stacked structures include gate layers and first insulating layers stacked alternately. The first slits and second slits are arranged alternatively in a first direction and extending in a second direction. The first slit includes a first sub-slit extending over the staircase region and a second sub-slit extending over the memory array region, and a spacer is between the first and the second sub-slit. The second slits extend from over the memory array region to over the staircase region.

### BACKGROUND

### Field of Disclosure

The present disclosure relates to a memory device and manufacturing method thereof.

### Description of Related Art

Since a non-volatile memory has the advantage that stored data does not disappear at power-off, it becomes a widely used memory for a personal computer or other electronics equipment. Currently, the three-dimensional (3D) memory commonly used in the industry includes a NOR memory and a NAND memory. In addition, another type of 3D memory is an AND memory, which may be applied to a multi-dimensional memory array with high integration and high area utilization, and has an advantage of a fast operation speed. Therefore, the development of a 3D memory device has gradually become the current trend. However, there are still many challenges associated with the 3D memory device.

### SUMMARY

A memory device according to an embodiment includes a substrate, a stacked structure, and a plurality of first slits and a plurality of second slits. The substrate has a memory array region and a staircase region. The stacked structure includes a first gate stacked structure and a plurality of second gate stacked structures. The first gate stacked structure is located over the memory array region, and the plurality of second gate stacked structures are located over the staircase region. The first gate stacked structure and the plurality of second gate stacked structures include a plurality of gate layers and a plurality of first insulating layers stacked alternately. The plurality of first slits and second slits are arranged alternatively in a first direction and extending in a second direction. Each of the plurality of first slits includes a first sub-slit extending over the staircase region and a second sub-slit extending over the memory array region, and a spacer is between the first sub-slit and the second sub-slit. The plurality of second slits extend from over the memory array region to over the staircase region.

A manufacturing method of forming a memory device according to an embodiment of the present disclosure includes forming a stacked structure over a substrate having a memory array region and a staircase region, which the stacked structure comprises a plurality of intermediate layers and a plurality of first insulating layers stacked alternately, and the stacked structure has a staircase structure over the staircase region; forming a first slit trench in the stacked structure over the staircase region; forming a first sub-slit of a first slit in the first slit trench; forming a second slit trench in the stacked structure aligned with the first sub-slit of the first slit in a first direction, and the second slit trench extending from over the memory array region to over the staircase region in a second direction; replacing the plurality of intermediate layers by a plurality of gate layers through the second slit trench to form a first gate stacked structure over the memory array region and a second gate stacked structure over the staircase region; and forming a second sub-slit of the first slit in the second slit trench, wherein the first sub-slit and the second sub-slit are separated by a spacer.

### BRIEF DESCRIPTION OF THE DRAWINGS

FIG. 1A is a circuit diagram of a 3D AND flash memory array according to some embodiments.

FIG. 1B is a partial perspective view of a part of the memory array in FIG. 1A.

FIG. 1C and FIG. 1D are cross-sectional views taken along line I-I′ of FIG. 1B.

FIG. 1E is a top view of line II-II′ of FIG. 1B, FIG. 1C, and FIG. 1D.

FIG. 2 is a top view of a memory device, according to an embodiment of the disclosure.

FIG. 3A is a top view of a tile in FIG. 2 according to an embodiment of the present disclosure.

FIG. 3B is a perspective view of a partial area of FIG. 3A.

FIG. 3C is a cross-sectional view taken along the line A-A′ of FIG. 3A according to an embodiment of the present disclosure.

FIG. 3D is a cross-sectional view taken along the line A-A′ of FIG. 3A according to another embodiment of the present disclosure.

FIG. 3E is a perspective view of a partial area of FIG. 3A.

FIG. 4A is a top view of a tile in FIG. 2 according to another embodiment of the present disclosure.

FIG. 4B is a perspective view of a partial area of FIG. 4A.

FIG. 4C is a cross-sectional view taken along the line B-B′ of FIG. 4A according to an embodiment of the present disclosure.

FIG. 4D is a perspective view of a partial area of FIG. 4A.

FIGS. 5A, 6A, 7A, 8A, 9A, 10A, and 11A are top views of a method of fabricating the memory device in some embodiments of the present disclosure. FIGS. 5B, 6B, 7B, 8B, 9B, 10B, and 11B are perspective views of a partial area in FIGS. 5A, 6A, 7A, 8A, 9A, 10A, and 11A.

FIG. 12A to FIG. 12B show schematic cross-sectional views of interfaces between insulating layers, a conductive layer, and intermediate layers during fabricating the memory device.

FIG. 13A to FIG. 13C show schematic cross-sectional views of various through vias in according to an embodiment of the present disclosure.

FIG. 14A to FIG. 14C show schematic cross-sectional views of various slits in according to an embodiment of the present disclosure.

### DETAILED DESCRIPTION

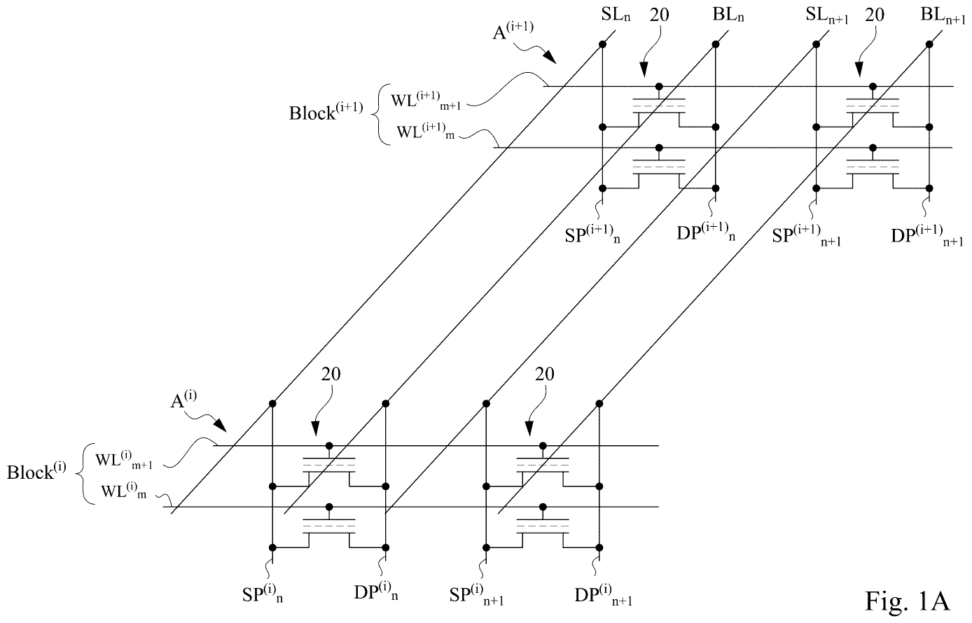

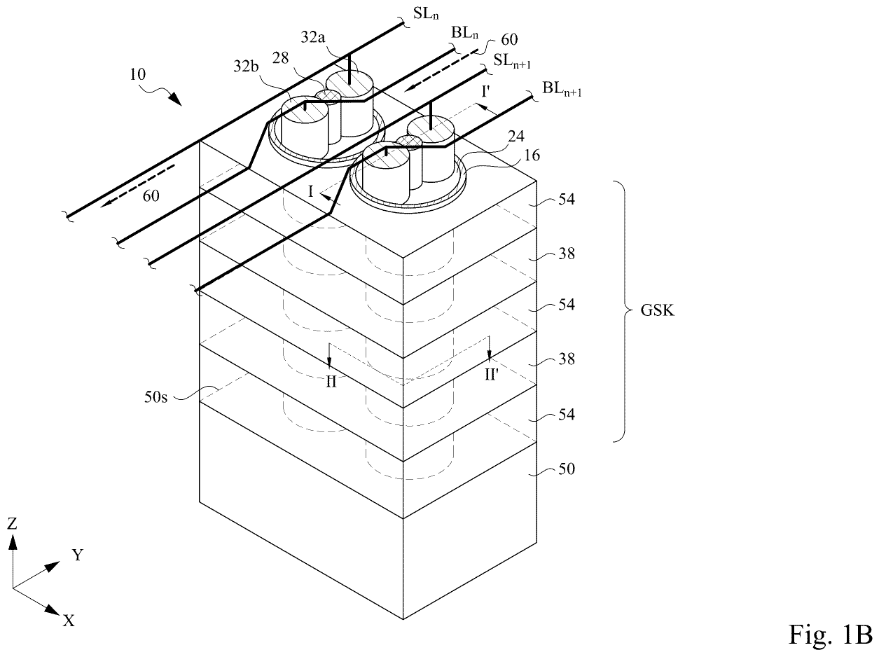

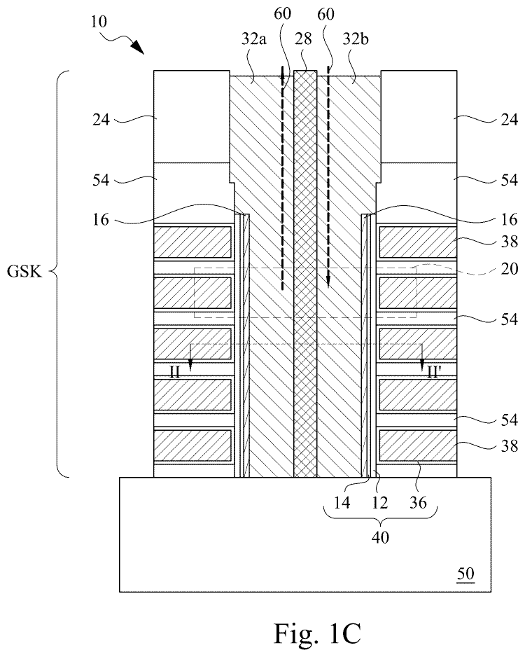

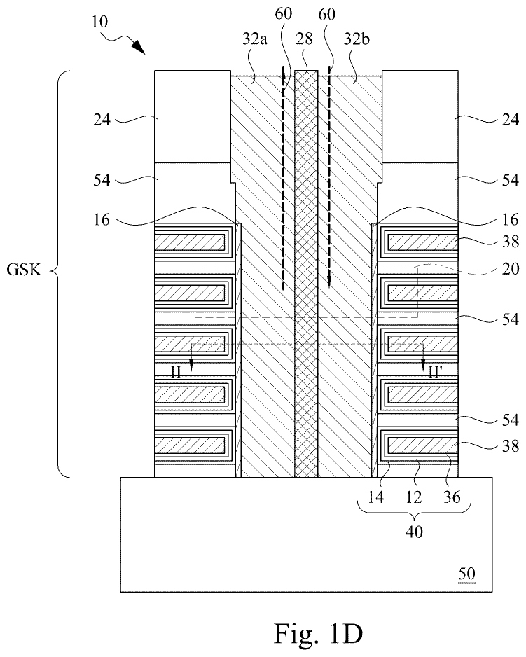

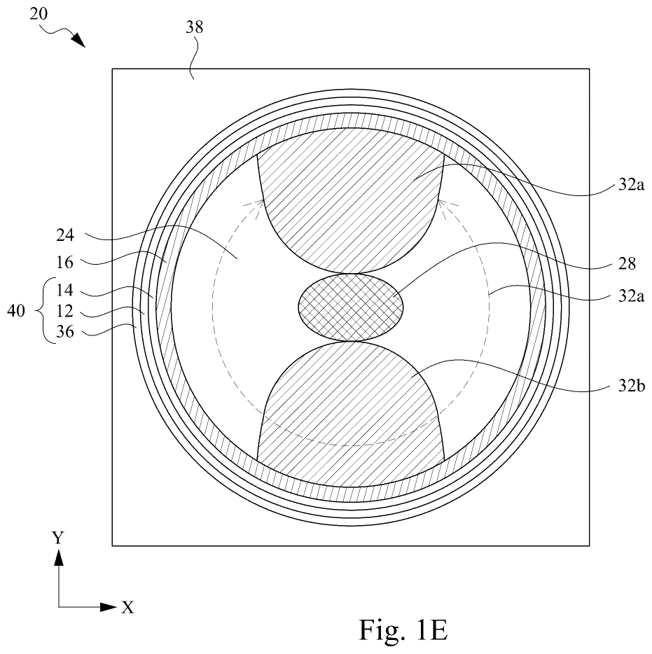

FIG. 1A is a circuit diagram of a 3D AND flash memory array according to some embodiments. FIG. 1B is a partial perspective view of a part of the memory array in FIG. 1A. FIG. 1C and FIG. 1D are cross-sectional views taken along line I-I′ of FIG. 1B. FIG. 1E is a top view of line II-II′ of FIG. 1B, FIG. 1C, and FIG. 1D.

FIG. 1A is a schematic view of two blocks BLOCK⁽ⁱ⁾ and BLOCK⁽ⁱ⁺¹⁾ of a vertical AND memory array 10 arranged in rows and columns. The block BLOCK⁽ⁱ⁾ includes a memory array A⁽ⁱ⁾. A row (e.g., an (m+1)th row) of the memory array A⁽ⁱ⁾ is a set of AND memory cells 20 having a common word line (e.g., WL⁽ⁱ⁾ₘ₊₁). The AND memory cells 20 of the memory array A⁽ⁱ⁾ in each row (e.g., the (m+1)th row) correspond to a common word line (e.g., WL⁽ⁱ⁾ₘ₊₁) and are coupled to different source pillars (e.g., SP⁽ⁱ⁾ₙ and SP⁽ⁱ⁾ₙ₊₁) and drain pillars (e.g., DP⁽ⁱ⁾ₙ and DP⁽ⁱ⁾ₙ₊₁), so that the AND memory cells 20 are logically arranged in a row along the common word line (e.g., WL⁽ⁱ⁾ₘ₊₁).

A column (e.g., an nth column) of the memory array A⁽ⁱ⁾ is a set of AND memory cells 20 having a common source pillar (e.g., SP⁽ⁱ⁾ₙ) and a common drain pillar (e.g., DP⁽ⁱ⁾ₙ). The AND memory cells 20 of the memory array A⁽ⁱ⁾ in each column (e.g., the nth column) correspond to different word lines (e.g., WL⁽ⁱ⁾ₘ₊₁ and WL⁽ⁱ⁾ₘ) and are coupled to a common source pillar (e.g., SP⁽ⁱ⁾ₙ) and a common drain pillar (e.g., DP⁽ⁱ⁾ₙ). Hence, the AND memory cells 20 of the memory array A⁽ⁱ⁾ are logically arranged in a column along the common source pillar (e.g., SP⁽ⁱ⁾ₙ) and the common drain pillar (e.g., DP⁽ⁱ⁾ₙ). In the physical layout, according to the fabrication method as applied, the columns or rows may be twisted and arranged in a honeycomb pattern or other patterns for high density or other reasons.

In FIG. 1A, in the block BLOCK⁽ⁱ⁾, the AND memory cells 20 in the nth column of the memory array A⁽ⁱ⁾ share a common source pillar (e.g., SP⁽ⁱ⁾ₙ) and a common drain pillar (e.g., DP⁽ⁱ⁾ₙ). The AND memory cells 20 in an (n+1)th column share a common source pillar (e.g., SP⁽ⁱ⁾ₙ₊₁) and a common drain pillar (e.g., DP⁽ⁱ⁾ₙ₊₁).

The common source pillar (e.g., SP⁽ⁱ⁾ₙ) is coupled to a common source line (e.g., SLₙ) and the common drain pillar (e.g., DP⁽ⁱ⁾ₙ) is coupled to a common bit line (e.g., BLₙ). The common source pillar (e.g., SP⁽ⁱ⁾ₙ₊₁) is coupled to a common source line (e.g., SLₙ₊₁) and the common drain pillar (e.g., DP⁽ⁱ⁾ₙ₊₁) is coupled to a common bit line (e.g., BLₙ₊₁).

Likewise, the block BLOCK⁽ⁱ⁺¹⁾ includes a memory array A⁽ⁱ⁺¹⁾, which is similar to the memory array A⁽ⁱ⁾ in the block BLOCK⁽ⁱ⁾. A row (e.g., an (m+1)th row) of the memory array A⁽ⁱ⁾ is a set of AND memory cells 20 having a common word line (e.g., WL⁽ⁱ⁺¹⁾ₘ₊₁). The AND memory cells 20 of the memory array A⁽ⁱ⁺¹⁾ in each row (e.g., the (m+1)th row) correspond to a common word line (e.g., WL⁽ⁱ⁺¹⁾ₘ₊₁) and are coupled to different source pillars (e.g., SP⁽ⁱ⁺¹⁾ₙ and SP⁽ⁱ⁺¹⁾ₙ₊₁) and drain pillars (e.g., DP⁽ⁱ⁺¹⁾ₙ and DP⁽ⁱ⁺¹⁾ₙ₊₁). A column (e.g., an nth column) of the memory array A⁽ⁱ⁺¹⁾ is a set of AND memory cells 20 having a common source pillar (e.g., SP⁽ⁱ⁺¹⁾ₙ) and a common drain pillar (e.g., DP⁽ⁱ⁺¹⁾ₙ). The AND memory cells 20 of the memory array A⁽ⁱ⁺¹⁾ in each column (e.g., the nth column) correspond to different word lines (e.g., WL⁽ⁱ⁺¹⁾ₘ₊₁ and WL⁽ⁱ⁺¹⁾ₘ) and are coupled to a common source pillar (e.g., SP⁽ⁱ⁺¹⁾ₙ) and a common drain pillar (e.g., DP⁽ⁱ⁺¹⁾ₙ). Hence, the AND memory cells 20 of the memory array A⁽ⁱ⁺¹⁾ are logically arranged in a column along the common source pillar (e.g., SP⁽ⁱ⁺¹⁾ₙ) and the common drain pillar (e.g., DP⁽ⁱ⁺¹⁾ₙ).

The block BLOCK⁽ⁱ⁺¹⁾ and the block BLOCK⁽ⁱ⁾ share source lines (e.g., SLₙ and SLₙ₊₁) and bit lines (e.g., BLₙ and BLₙ₊₁). Therefore, the source line SLₙ and the bit line BLₙ are coupled to the nth column of AND memory cells 20 in the AND memory array A⁽ⁱ⁾ of the block BLOCK⁽ⁱ⁾, and are coupled to the nth column of AND memory cells 20 in the AND memory array A⁽ⁱ⁺¹⁾ of the block BLOCK⁽ⁱ⁺¹⁾. Similarly, the source line SLₙ₊₁ and the bit line BLₙ₊₁ are coupled to the (n+1)th column of AND memory cells 20 in the AND memory array A⁽ⁱ⁾ of the block BLOCK⁽ⁱ⁾, and are coupled to the (n+1)th column of AND memory cells 20 in the AND memory array A⁽ⁱ⁺¹⁾ of the block BLOCK⁽ⁱ⁺¹⁾.

Referring to FIG. 1B to FIG. 1D, the memory array 10 may be disposed over an interconnection structure of a semiconductor die, for example, being disposed on one or more active devices (e.g., transistors) formed on a semiconductor substrate. Therefore, a dielectric substrate 50 may be a dielectric layer (e.g., a silicon oxide layer) over a metal interconnection structure formed on a silicon substrate. The memory array 10 may include a stacked structure GSK, multiple channel pillars 16, multiple first conductive pillars (also referred to as source pillars) 32a, multiple second conductive pillars (also referred to as drain pillars) 32b, and multiple charge storage structures 40.

Referring to FIG. 1B, the stacked structure GSK is formed on the dielectric substrate 50. The stacked structure GSK includes multiple gate layers (also referred to as word lines or conductive layers) 38 and multiple insulating layer 54 vertically stacked on a surface 50 s of the dielectric substrate 50. In a direction Z, the gate layers 38 are electrically isolated from each other by the insulating layer 54 disposed therebetween. The gate layers 38 extend in a direction parallel to the surface of the dielectric substrate 50. The gate layers 38 in the staircase region SR may have a staircase structure SC. Therefore, a lower gate layer 38 is longer than an upper gate layer 38, and the end of the lower gate layer 38 extends laterally beyond the end of the upper gate layer 38. Contacts (not shown) for connecting the gate layers 38 may be landed on the ends of the gate layers 38 to connect the gate layers 38 respectively to conductive lines.

Referring to FIG. 1B to FIG. 1D, the memory array 10 further includes multiple channel pillars 16. The channel pillars 16 extend continuously through the stacked structure GSK and to the conductive layer 53 between the dielectric substrate 50 and the stacked structure GSK. The material of the conductive layer 53 may include doped polysilicon. For example, the material of the conductive layer 53 may include P-type doped polysilicon. In some embodiments, each channel pillar 16 may have a ring shape from a top view. The material of the channel pillars 16 may include semiconductor, such as undoped polysilicon.

Referring to FIG. 1B to FIG. 1D, the memory array 10 further includes multiple insulating pillars 28, multiple first conductive pillars 32a, and multiple second conductive pillars 32b. In this example, the first conductive pillars 32a serve as source pillars. The second conductive pillars 32b serve as drain pillars. The first conductive pillars 32a, the second conductive pillars 32b, and the insulating pillars 28 each extend in a direction (i.e., the direction Z) perpendicular to the surface (i.e., the X-Y plane) of the gate layer 38. The first conductive pillar 32a and the second conductive pillar 32b are separated by the insulating pillar 28 and surrounded by an insulating filling layer 24. The first conductive pillar 32a and the second conductive pillar 32b are electrically connected to the channel pillar 16. The first conductive pillar 32a and the second conductive pillar 32b may include doped polysilicon or metal materials. The insulating pillar 28 may include silicon nitride or silicon oxide, and the insulating filling layer 24 may include silicon oxide.

Referring to FIG. 1C and FIG. 1D, a charge storage structure 40 is disposed between the channel pillar 16 and the gate layers (or called conductive layers) 38. The charge storage structure 40 may include a tunneling layer (or referred to as a band gap engineered tunneling oxide layer) 14, a charge storage layer 12, and a blocking layer 36. The charge storage layer 12 is located between the tunneling layer 14 and the blocking layer 36. In some embodiments, the tunneling layer 14 and the blocking layer 36 include silicon oxide. The charge storage layer 12 includes silicon nitride or other materials capable of trapping charges. In some embodiments, as shown in FIG. 1C, a portion (e.g., the tunneling layer 14 and the charge storage layer 12) of the charge storage structure 40 continuously extends in a direction (i.e., the direction Z) perpendicular to the gate layer 38, and another portion (e.g., the blocking layer 36) of the charge storage structure 40 surrounds the gate layer 38. In other embodiments, as shown in FIG. 1D, the charge storage structure 40 (e.g., the tunneling layer 14, the charge storage layer 12, and the blocking layer 36) surrounds the gate layer 38.

Referring to FIG. 1E, the charge storage structure 40, the channel pillar 16, the source pillar 32a, and the drain pillar 32b are surrounded by the gate layer 38, and a memory cell 20 is accordingly defined. According to different operation methods, a 1-bit operation or a 2-bit operation may be performed on the memory cell 20. For example, when a voltage is applied to the source pillar 32a and the drain pillar 32b, since the source pillar 32a and the drain pillar 32b are connected to the channel pillar 16, electrons may be transferred along the channel pillar 16 and stored in the entire charge storage structure 40. Accordingly, a 1-bit operation may be performed on the memory cell 20. In addition, for an operation involving Fowler-Nordheim tunneling, electrons or holes may be trapped in the charge storage structure 40 between the source pillar 32a and the drain pillar 32b. For an operation involving source side injection, channel-hot-electron injection, or band-to-band tunneling hot carrier injection, electrons or holes may be locally trapped in the charge storage structure 40 adjacent to one of the source pillar 32a and the drain pillar 32b. Accordingly, a single level cell (SLC, 1 bit) or multi-level cell (MLC, greater than or equal to 2 bits) operation may be performed on the memory cell 20.

During operation, a voltage is applied to a selected word line (gate layer) 38; for example, when a voltage higher than a corresponding threshold voltage (Vth) of the corresponding memory cell 20 is applied, a channel region of the channel pillar 16 intersecting the selected word line 38 is turned on to allow a current to enter the drain pillar 32b from the bit line BLₙ or BLₙ₊₁ (shown in FIG. 1B), flow to the source pillar 32a via the turned-on channel region (e.g., in a direction indicated by arrow 60), and finally flow to the source line SLₙ or SLₙ₊₁ (shown in FIG. 1B) .

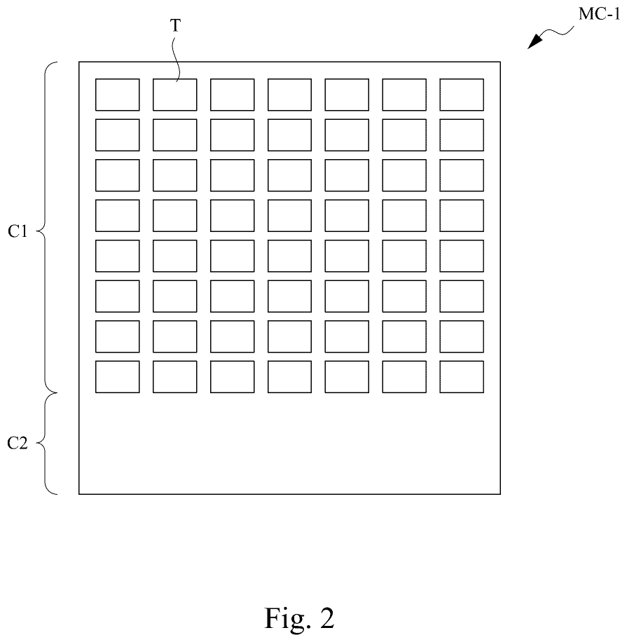

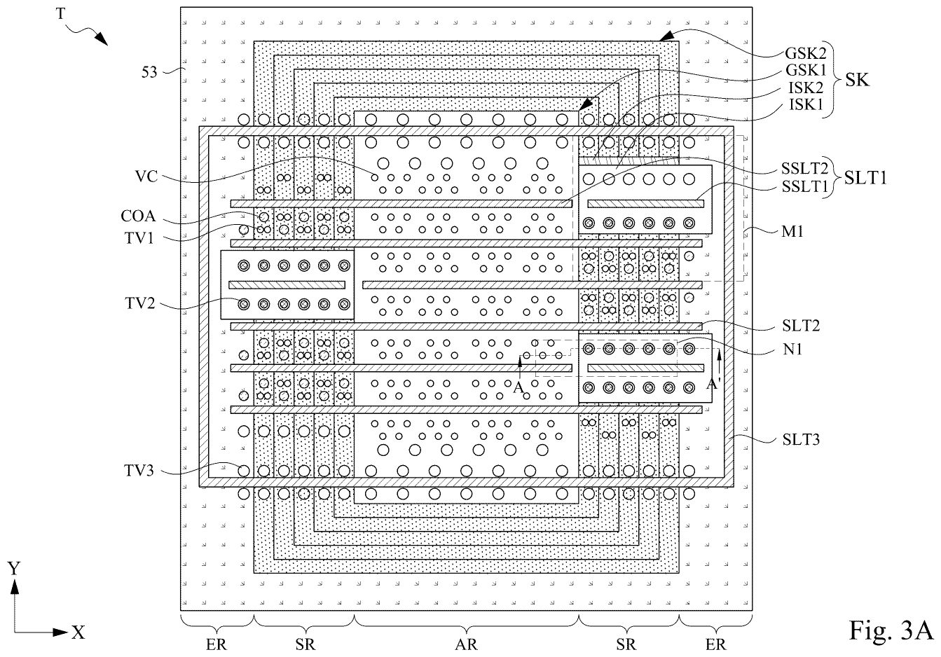

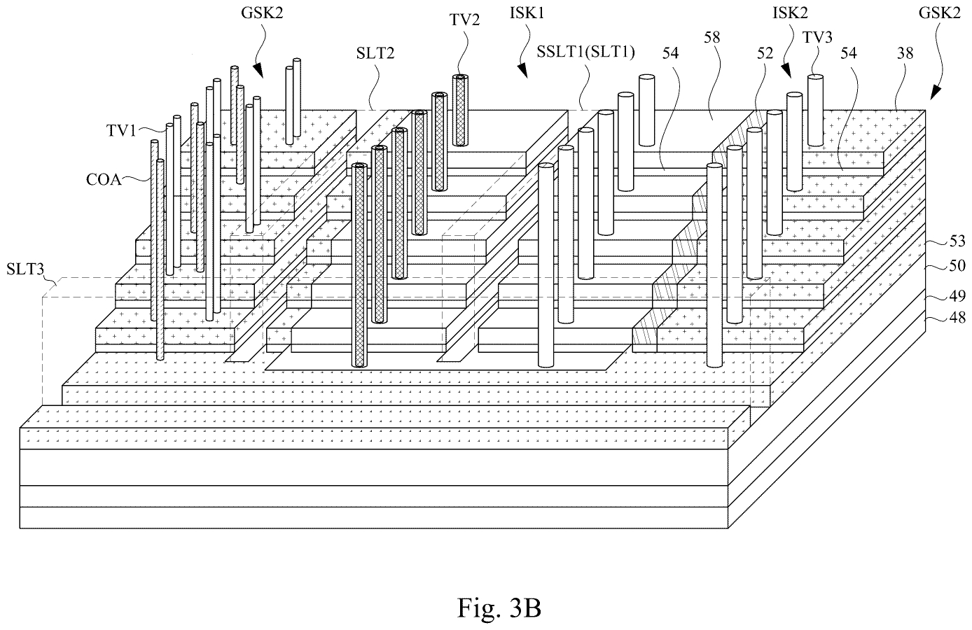

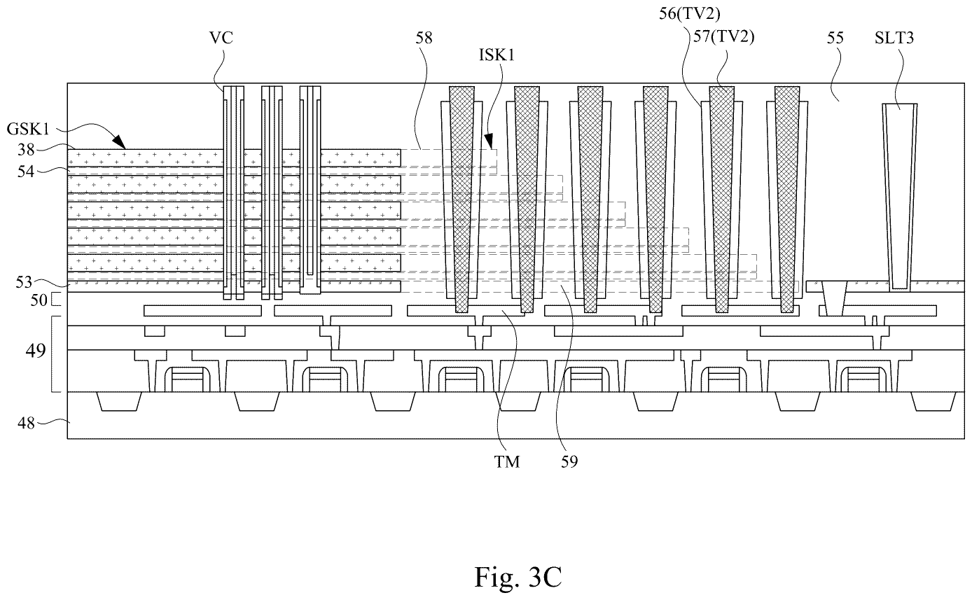

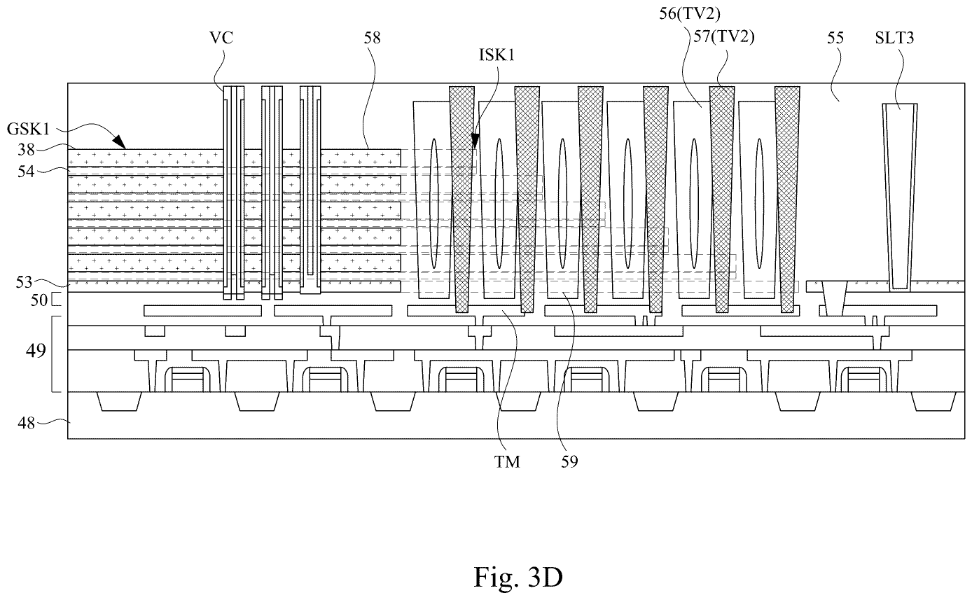

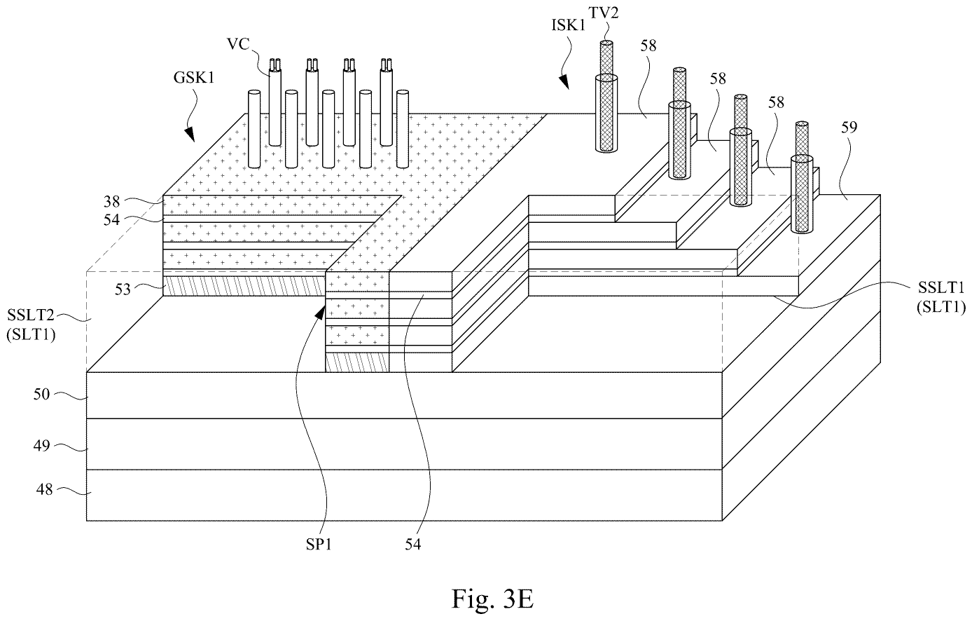

FIG. 2 is a top view of a memory device, according to an embodiment of the disclosure. FIG. 3A is a top view of a tile T in FIG. 2 according to an embodiment of the present disclosure. FIG. 3B is a perspective view of a partial area M1 of FIG. 3A. FIG. 3C is a cross-sectional view taken along the line A-A′ of FIG. 3A according to an embodiment of the present disclosure. FIG. 3D is a cross-sectional view taken along the line A-A′ of FIG. 3A according to another embodiment of the present disclosure. FIG. 3E is a perspective view of a partial area N1 of FIG. 3A.

Referring to FIG. 2 and FIG. 3A, a memory chip MC-1 may be an AND memory device. The memory chip MC-1 may include a region C1 and a region C2. The region C1 may include multiple tiles T separated from each other. The tiles T may be arranged in an array with multiple rows and multiple columns. In FIG. 2, the tile array is formed by seven rows and eight columns, but the embodiment of the present disclosure is not limited thereto. Each tile T in the region C1 has multiple memory arrays. The region C2 includes peripheral circuits, such as complementary metal oxide semiconductor devices (CMOS), disposed on the periphery of the tile array.

Referring to FIG. 3A and FIG. 3B. The memory chip MC-1 includes a substrate 48, an interconnection structure 49, a dielectric substrate 50, a conductive layer 53, a stacked structure SK, and a plurality of first slits SLT1, a plurality of second slits SLT2 and a third slit SLT3. The substrate 48 includes a memory array region AR, a staircase region SR, and an edge region ER. The memory array region AR is surrounded by the staircase region SR, and the staircase region SR is surrounded by the edge region ER. The interconnection structure 49, the dielectric substrate 50, the conductive layer 53, and the stacked structure SK are over the substrate 48. The stacked structure SK includes a gate stacked structure GSK1, gate stacked structures GSK2, and insulating stacked structures ISK1. The gate stacked structure GSK1 is at the memory array region AR. The gate stacked structures GSK2 and the insulating stacked structures ISK1 are arranged in Y direction alternately at the staircase region SR. The gate stacked structures GSK1 and GSK2 include a plurality of gate layers 38 and a plurality of insulating layers 54 stacked alternately. The insulating stacked structure ISK1 includes a plurality of insulating layers 58 and a plurality of insulating layers 54 stacked alternately. The insulating layers 58 are adjacent to the gate layers 38, and the insulating layers 54 extend from the gate stacked structure GSK2 to the insulating stacked structure ISK1. The gate stacked structures GSK2 and the insulating stacked structures ISK1 at the staircase region SR have staircase structures.

In the present disclosure, the gate layers 38 of the gate stacked structures GSK1 and GSK2 are replaced by intermediate layers 52. However, a portion of the intermediate layers 52 of the present disclosure will not be replaced by the gate layers 38 eventually, but will remain in the memory device to form an insulating stacked structure ISK2. The insulating stacked structure ISK2 includes a plurality of intermediate layers 52 and a plurality of insulating layers 54 stacked alternately. The insulating stacked structure ISK2 may be between the insulating stacked structure ISK1 and the gate stacked structure GSK2. In addition, a portion of the intermediate layer 52 of the present disclosure will not be replaced by a plurality of gate layers 38, but will be replaced by insulating layers 58 adjacent to the gate layers 38. In addition, a portion of the conductive layer 53 of the present disclosure will be replaced by an insulating layer 59. The insulating layer 59 is adjacent to the conductive layer 53. As a result, the conductive layer 53 remains under the gate stacked structure GSK1, and is between the gate stacked structure GSK1 and the substrate 48. The insulating layer 59 is under the insulating stacked structure ISK1 and is between the insulating stacked structure ISK1 and the substrate 48.

The third slit SLT3 surrounds the periphery of the first slits SLT1 and the second slits SLT2, and the first slits SLT1 and the second slits SLT2 are formed inside the third slit SLT3. The third slit SLT3 may be circular from a top view. The first slits SLT1 and the second slits SLT2 are long strips extending in the X direction and arranged alternatively in the Y direction. In some embodiments, the Y direction is also called the first direction, the X direction is also called the second direction, and the Z direction is also called the third direction. The first slit SLT1 includes a first sub-slit SSLT1 and second sub-slit SSLT2. The first sub-slit SSLT1 extends over the staircase region SR, and the second sub-slit SSLT2 extends over the memory array region AR. A spacer (such as spacer SP1 shown in FIG. 3E) is between the first sub-slit SSLT1 and the second sub-slit SSLT2. The second slit SLT2 extends from over the memory array region AR and to over the staircase region SR.

Referring to FIG. 3A, FIG. 3B and FIG. 3C, the memory device includes multiple contacts COA, multiple through vias TV1, multiple through vias TV2, and multiple through vias TV3. Referring to FIG. 3A and FIG. 3B, multiple contacts COA are located at the staircase region SR, penetrate through the dielectric layer 55 and the gate stacked structure GSK2, and are electrically connected to the gate layers 38 or the blocking layers (not shown) of the steps of the gate stacked structure GSK2, respectively. The contacts COA include conductive materials.

Referring to FIG. 3A, FIG. 3B and FIG. 3C, multiple through vias TV1 are located at the staircase region SR, penetrate through the dielectric layer 55 and the gate stacked structure GSK2, and extend to the conductive layer 53. Each through via TV1 includes an insulating pillar, and is electrically isolated from the gate layers 38 of the gate stacked structure GSK2 and electrically isolated from the interconnection structure 49. Therefore, the through vias TV1 are also called insulating through vias TV1.

Referring to FIG. 3A, FIG. 3B and FIG. 3C, multiple through vias TV2 are located at the staircase region SR and the edge region ER, penetrate through the dielectric layer 55, the insulating stacked structure ISK1, and the insulating layer 59, and extend to the conductive layer 53 and the interconnection structure 49, and are landed on and electrically connected to the topmost conductive layer TM of the interconnection structure 49. Therefore, the through vias TV2 are also called conductive through vias TV2. Each through via TV2 includes an insulating pillar 56 and a conductive via 57. The insulating pillar 56 penetrates through the dielectric layer 55 and extends through the conductive layer 53. The conductive via 57 is located in the insulating pillar 56 and penetrates through the insulating pillar 56 and the dielectric substrate 50, and is landed on and electrically connected to the topmost conductive layer TM of the interconnection structure 49. In the embodiments sown in FIGS. 3A-3C, all the through vias TV2 are surrounded by the insulating stacked structure ISK1 and the insulating layer 59, and the gate layers 38 of the gate stacked structure GSK2 and the through vias TV2 do not overlap in a top view.

Referring to FIG. 3A, FIG. 3B and FIG. 3C, multiple through vias TV3 are located at the memory array structure AR, the staircase region SR and the edge region ER, penetrate through the dielectric layer 55 and the gate stacked structure GSK2 (or the insulating stacked structure ISK1), and extend to the conductive layer 53. Each through via TV3 includes an insulating pillar, and is electrically isolated from the gate layers 38 of the gate stacked structure GSK2 and electrically isolated from the interconnection structure 49. Therefore, the through vias TV3 are also called insulating through vias TV3.

In some embodiments, the diameter of the through vias TV2 is greater than the diameter of the through vias TV1 or/and greater than the diameter of the contacts COA. The diameter of the through vias TV2 is substantially the same as the diameter of the through vias TV3.

Referring to FIG. 3C, the insulating pillar 56 and the conductive via 57 of the through via TV2 have a structure that is wide at the top and narrow at the bottom. Generally, in the lower part of the through via TV2, especially when surrounded by the conductive layer 53 and the lower portion of the gate layers 38, the width of the insulating pillar 56 of the through via TV2 may be too narrow, so that the conductive via 57 may not be entirely wrapped by the insulating pillar 56. Therefore, the conductive via 57 may in contact with the conductive layer 53 and the gate layers 38. This may cause leakage current between the through hole TV2 and the conductive layer 53 and the gate layers 38. In the present disclosure, in order to avoid the above situation, the gate layers 38 are replaced by the insulating layers 58, and the conductive layer 53 is replaced by the insulating layer 59, so that the through via TV2 and the gate layers 38 of the gate stacked structure GSK2 are separated by the insulating layers 58, and the through hole TV2 and the conductive layer 53 are separated by the insulating layer 59. This can reduce the probability of leakage current between the through via TV2 and the conductive layer 53 and the gate layers 38.

Referring to FIG. 3D, the conductive via 57 of the through hole TV2 may not be entirely wrapped by the insulating pillar 56, such that the conductive via 57 of the through hole TV2 is directly in contact with the insulating stacked structure ISK1, the dielectric layer 55, and the insulating layer 59. In this situation, the gate layers 38 are replaced by the insulating layers 58, and the conductive layer 53 is replaced by the insulating layer 59. Therefore, even if the conductive via 57 is not entirely wrapped by the insulating pillar 56, the conductive via 57 is not in contact with the gate layers 38 and the conductive layer 53 to cause the leakage current between the through via TV2 and the conductive layer 53 and the gate layers 38.

Referring to FIG. 3E, the first sub-slit SSLT1 of the first slit SLT1 is not directly contact with the second sub-slit SSLT2 of the first slit SLT1, and the first sub-slit SSLT1 of the first slit SLT1 and the second sub-slit SSLT2 of the first slit SLT1 are separated by a spacer SP1. In the embodiment of FIG. 3A, the first sub-slit SSLT1 is surrounded by the insulating stacked structure ISK1 and the insulating layer 59, and the second sub-slit SSLT2 is surrounded by the gate stacked structure GSK1 and the conductive layer 53. Therefore, the spacer SP1 may include a portion of the gate stacked structure GSK1, a portion of the conductive layer 53, a portion of the insulating stacked structure ISK1 and a portion of the insulating layer 59, and the first sub-slit SSLT1 and the conductive layer 53 are separated by the insulating layer 59. In some embodiments, the spacer SP1 has an interface between the gate stacked structure GSK1 and the insulating stacked structure ISK1, and has an interface between the conductive layer 53 and the insulating layer 59. In some embodiments, the first sub-slit SSLT1 and the second sub-slit SSLT2 may be each selected from a material selected from the group consisting of silicon oxide, polysilicon wrapped by silicon oxide, and silicon oxide with air gaps, and the first sub-slit SSLT1 and the second sub-slit SSLT2 may be made of the same or different materials.

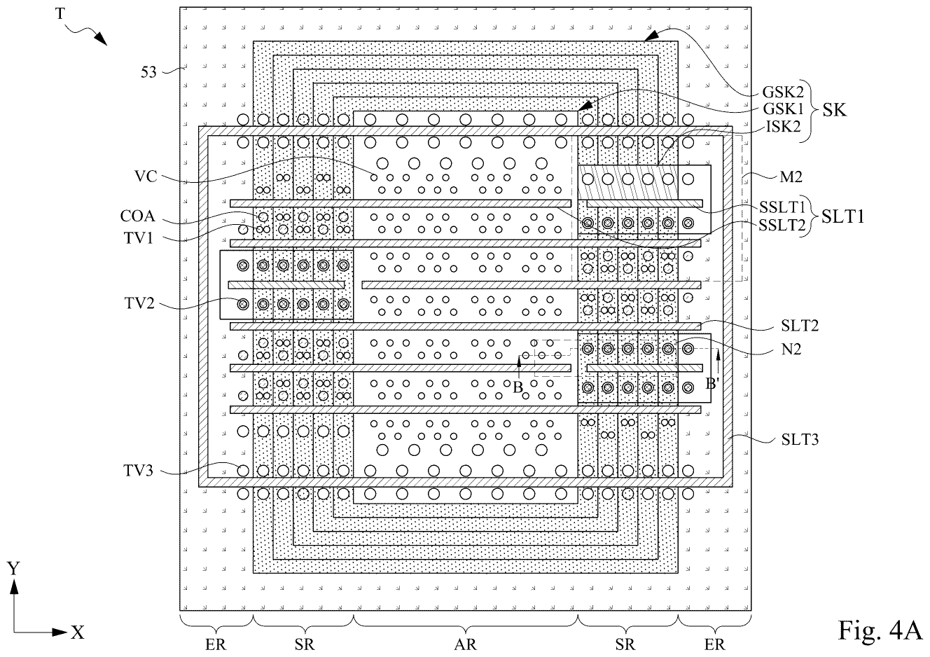

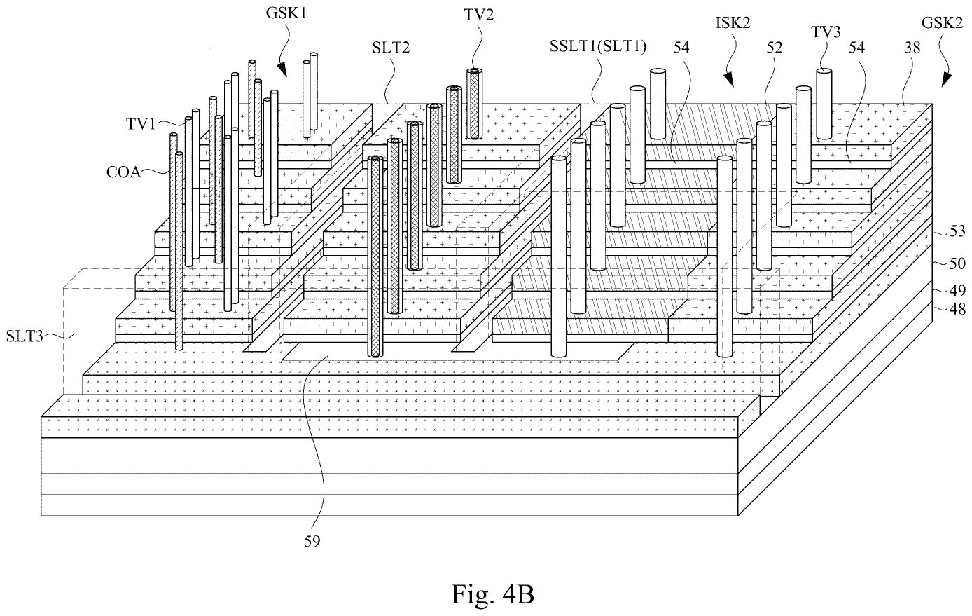

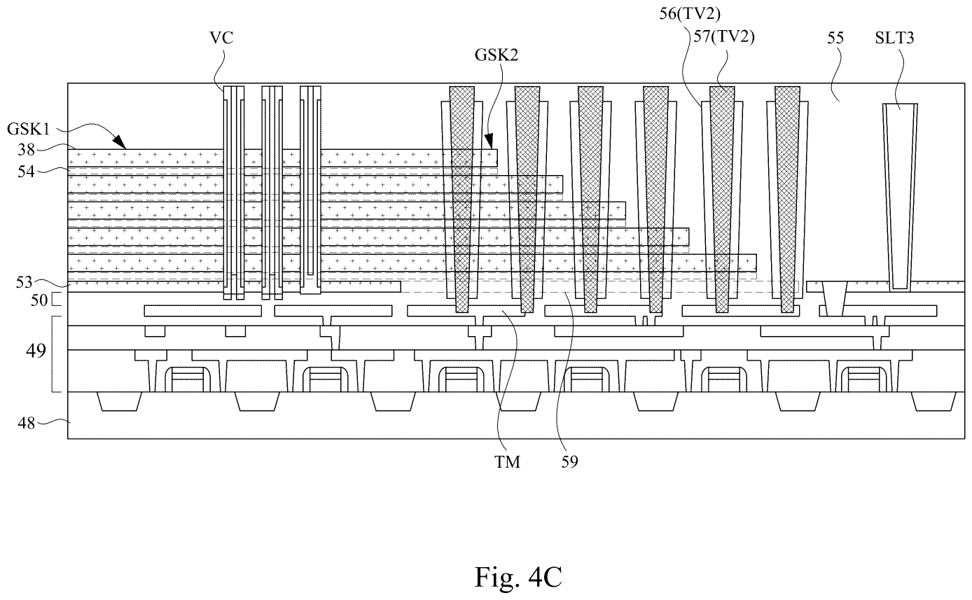

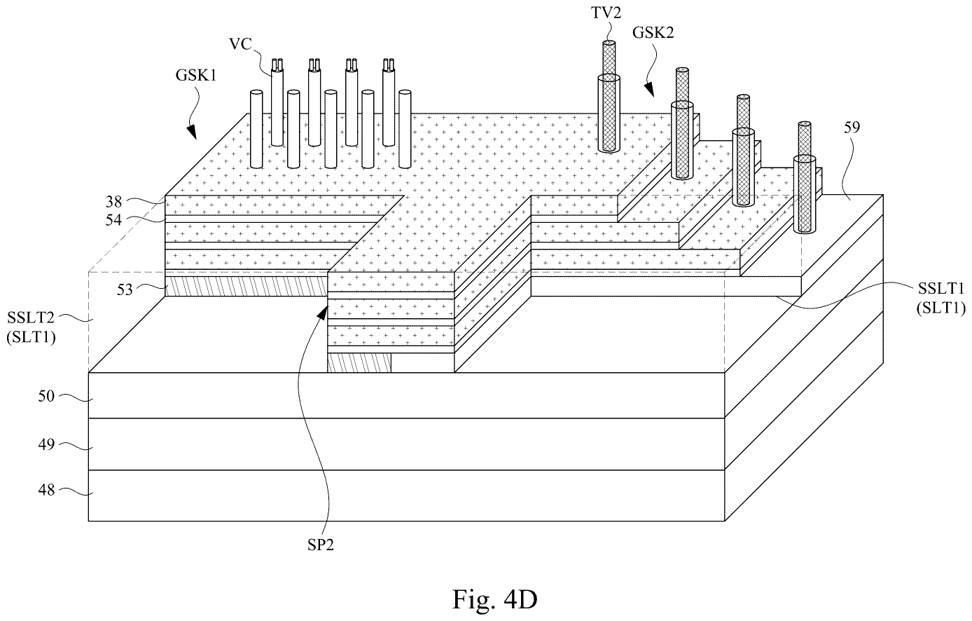

FIG. 4A is a top view of a tile T in FIG. 2 according to another embodiment of the present disclosure. FIG. 4B is a perspective view of a partial area M2 of FIG. 4A. FIG. 4C is a cross-sectional view taken along the line B-B′ of FIG. 4A according to an embodiment of the present disclosure. FIG. 4D is a perspective view of a partial area N2 of FIG. 4A.

The tile T shown in FIG. 4A and FIG. 4B is similar to the tile T shown in FIG. 3A. The difference is that, in FIG. 4A and FIG. 4B, a portion of the intermediate layers 52 of the present disclosure will not be replaced by a plurality of gate layers 38 eventually, but will remain in the memory device. The remaining intermediate layers 52 will eventually be replaced by a plurality of gate layers 38. That is, the gate layers 38 are not replaced by the insulating layers 58. As a result, the conductive layer 53 remains under the gate stacked structure GSK1 and a portion of the gate stacked structure GSK2, and is between the gate stacked structure GSK1 and the substrate 48, and between a portion of the gate stacked structure GSK2 and the substrate 48. The insulating layer 59 is under the other portion of the gate stacked structure GSK2 and is between the other portion of the gate stacked structure GSK2 and the substrate 48.

Referring to FIGS. 4A-4C, the insulating pillar 56 and the conductive via 57 of the through via TV2 have a structure that is wide at the top and narrow at the bottom. Generally, in the lower part of the through via TV2, especially when surrounded by the conductive layer 53, the width of the insulating pillar 56 of the through via TV2 may be too narrow, so that the conductive via 57 may not be entirely wrapped by the insulating pillar 56. Therefore, the conductive via 57 may be in contact with the conductive layer 53. This may cause leakage current between the through via TV2 and the conductive layer 53. In the present disclosure, in order to avoid the above situation, the conductive layer 53 is replaced by the insulating layer 59, so that the through hole TV2 and the conductive layer 53 are separated by the insulating layer 59. This can reduce the probability of leakage current between the through via TV2 and the conductive layer 53.

Referring to FIG. 4D, the first sub-slit SSLT1 of the first slit SLT1 is not directly contact with the second sub-slit SSLT2 of the first slit SLT1, and the first sub-slit SSLT1 and the second sub-slit SSLT2 are separated by a spacer SP2. In the embodiment of FIG. 4A, the first sub-slit SSLT1 is surrounded by the gate stacked structure GSK2 and the insulating layer 59, and the second sub-slit SSLT2 is surrounded by the gate stacked structure GSK1 and the conductive layer 53. Therefore, the spacer SP2 may include a portion of the gate stacked structure GSK1, GSK2, a portion of the conductive layer 53, and a portion of the insulating layer 59, and the first sub-slit SSLT1 and the conductive layer 53 are separated by the insulating layer 59. In some embodiments, the spacer SP1 has an interface between the conductive layer 53 and the insulating layer 59.

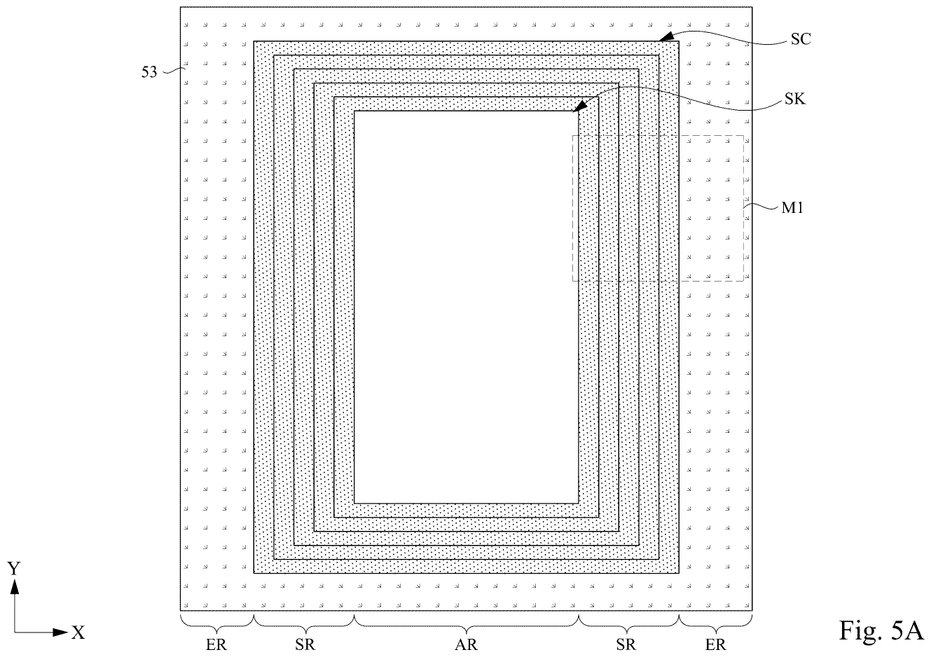

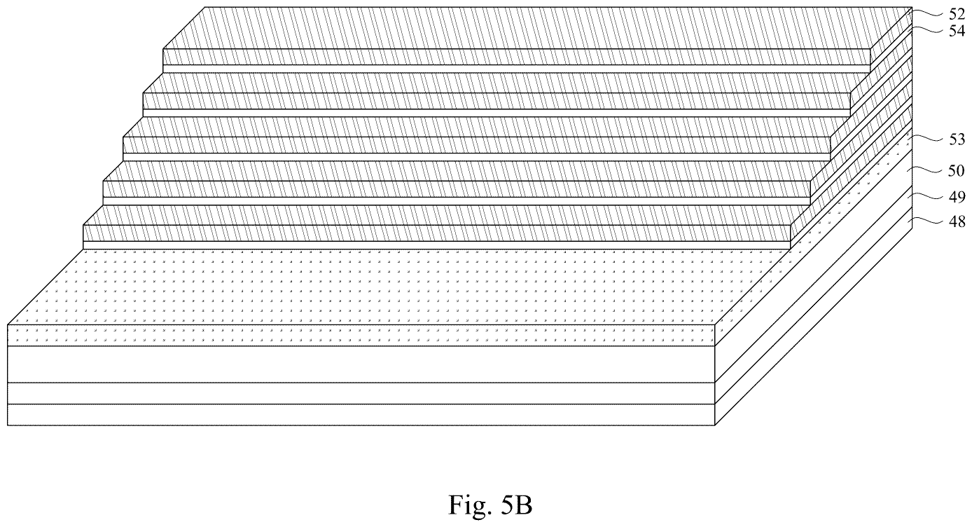

FIGS. 5A, 6A, 7A, 8A, 9A, 10A, and 11A are top views of a method of fabricating the memory device in some embodiments of the present disclosure. FIGS. 5B, 6B, 7B, 8B, 9B, 10B, and 11B are perspective views of a partial area M1 in FIGS. 5A, 6A, 7A, 8A, 9A, 10A, and 11A.

Referring to FIG. 5A and FIG. 5B, a substrate 48 is provided. The substrate 48 includes an array region AR, a staircase region SR and an edge region ER. The substrate 48 may include a semiconductor substrate, such as a silicon substrate. The substrate 48 may include components such as active elements (such as PMOS, NMOS, CMOS, JFET, BJT, or diodes) or passive elements. An interconnection structure 49 is formed on the array region AR and the staircase region SR of the substrate 48. The interconnection structure 49 may include components such as an intra-layer dielectric layer, a contact, a wire, an interlayer dielectric layer, and a via. The material of each of the intra-layer dielectric layer and the interlayer dielectric layer may include a silicon oxide layer. Next, a dielectric substrate 50 is formed on the interconnection structure 49. The material of the dielectric substrate 50 may include silicon oxide.

Continue referring to FIG. 5A and FIG. 5B, a blanket-type conductive layer 53 is formed on the dielectric substrate 50 in the array region AR and the staircase region SR. The conductive layer 53 also extends to the edge region ER. The conductive layer 53 may include a grounded P-type doped polysilicon layer. The conductive layer 53 can also be called a dummy gate, which can be used to close a leakage path.

Continue referring to FIG. 5A and FIG. 5B, a stacked structure SK is formed on the conductive layer 53, and the stacked structure SK is patterned to form a staircase structure SC of the stacked structure SK at the staircase region SR. In this embodiment, the stacked structure SK includes insulating layers 54 and the intermediate layer 52 that are sequentially alternately stacked on the conductive layer 53. In addition, in this embodiment, the uppermost layer of the stacked structure SK is the insulating layer 54. The material of the insulating layers 54 may include silicon oxide. The material of the intermediate layers 52 may include silicon nitride. The intermediate layers 52 can be used as sacrificial layers, which are partially removed in the subsequent processes. In this embodiment, the number of the insulating layers 54 and the intermediate layers 52 may be formed according to actual needs.

A dielectric layer 55 (as shown in FIG. 3C) is formed on the substrate 48 to cover the stacked structure SK. The material of the dielectric layer 55 may include silicon oxide. The method of forming the dielectric layer 55 may include forming a dielectric material to fill the stacked structure SK. Afterwards, a planarization process is performed by chemical mechanical polishing process, for example. For clarity, the dielectric layer 55 is not shown in FIG. 5A and FIG. 5B.

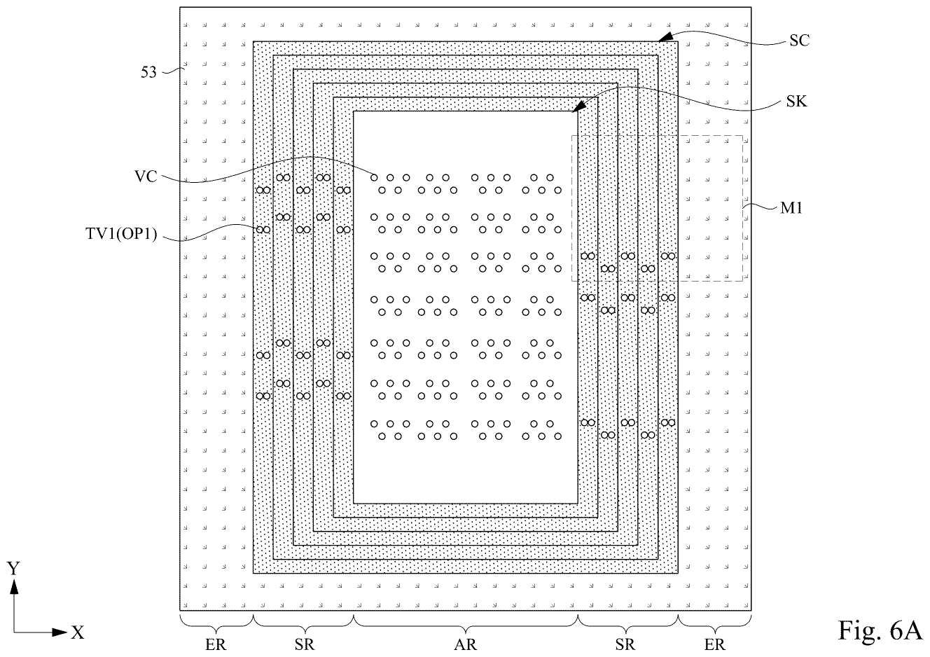

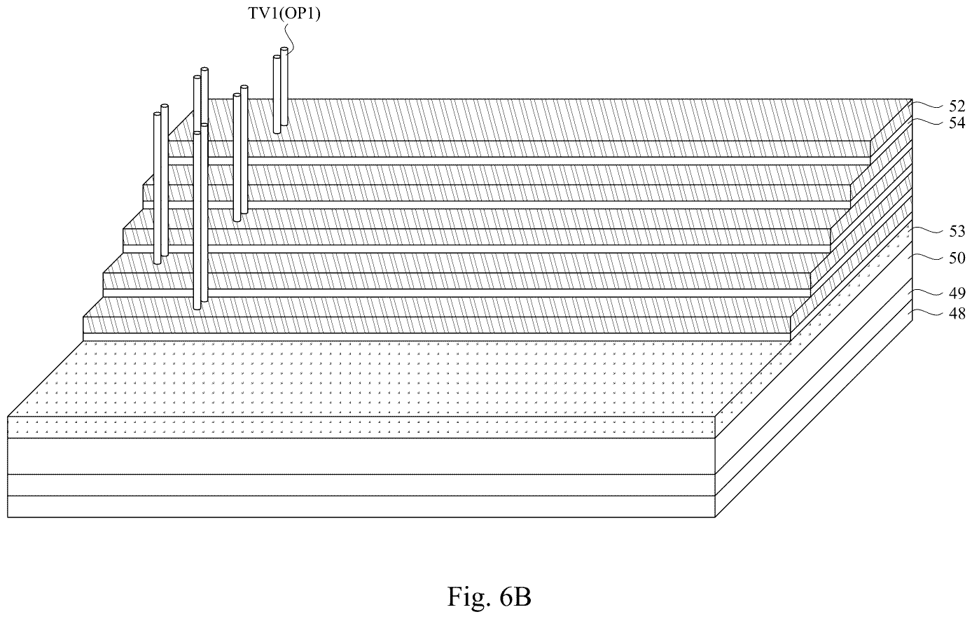

Referring to FIG. 6A and FIG. 6B, multiple openings VC are formed in the stacked structure SK. The openings VC expose the conductive layer 53. The etching process may include a dry etching process, a wet etching process or a combination thereof. The dry etching process may include a plasma etching process. In this embodiment, from the top view, the opening VC has a circular shape, but the disclosure is not limited thereto. In other embodiments, the opening VC may have other shapes, such as a polygon shape (not shown). Next, in some embodiments, the tunneling layer 14 and the channel pillar 16 are formed in the opening VC, as shown in FIG. 1D and FIG. 1E. The tunneling layer 14 may be formed in the subsequent processes. For simplicity, the channel pillar 16 and the tunneling layer 14 are not shown in FIG. 6A and FIG. 6B.

Referring to FIG. 1D and FIG. 1E, the tunneling layer 14 and the channel pillar 16 may penetrate through the stacked structure SK but do not penetrate through the conductive layer 53, but the present disclosure is not limited thereto. The channel pillar 16 may be annular from a top view, and may be continuous in its extending direction (e.g., in a direction perpendicular to the surface of the substrate 48). That is to say, the channel pillar 16 is integral in its extending direction, and is not divided into multiple disconnected parts. In some embodiments, the channel pillar 16 may have a circular shape from a top view, but the present disclosure is not limited thereto. In other embodiments, the channel pillar 16 may also have other shapes (such as polygonal shape) from a top view.

Referring to FIG. 1D and FIG. 1E, an insulating filling material is formed on the stacked structure SK and filled in the openings VC. The insulating filling material may include low-temperature silicon oxide. The insulating filling material filled in the opening VC forms an insulating filling layer 24, and a circular void is left at the center of the insulating filling layer 24. Then, an anisotropic etching process is performed to enlarge the circular void to form a hole. An insulating material is formed on the insulating filling layer 24 and filled in the hole. Then, an anisotropic etching process is performed to remove a part of the insulating material to form an insulating pillar 28 in the hole. The material of the insulating pillar 28 is different from the material of the insulating filling layer 24. The material of the insulating pillar 28 may include silicon nitride.

Referring to FIG. 1D and FIG. 1E, a patterning processes (e.g., lithography and etching processes) is performed to form holes (not shown) in the insulating filling layer 24. During the etching process, the conductive layer 53 may serve as an etching stop layer. Therefore, the formed holes extend from the stacked structure SK to the exposed conductive layer 53. The profiles of the hole patterns defined in the patterning process may be tangent to the profile of the insulating pillar 28. The profiles of the hole patterns defined in the patterning process may also exceed the profile of the insulating pillar 28 (not shown).

Referring to FIG. 1D and FIG. 1E, conductive pillars 32a and 32b are formed in the holes. The conductive pillars 32a and 32b may serve as source and drain pillars respectively, and are electrically connected to the channel pillar 16 respectively. The conductive pillars 32a and 32b can be formed by forming a conductive layer on the insulating filling layer 24 and in the holes, and followed by an etching back. The conductive pillars 32a and 32b may include doped polysilicon.

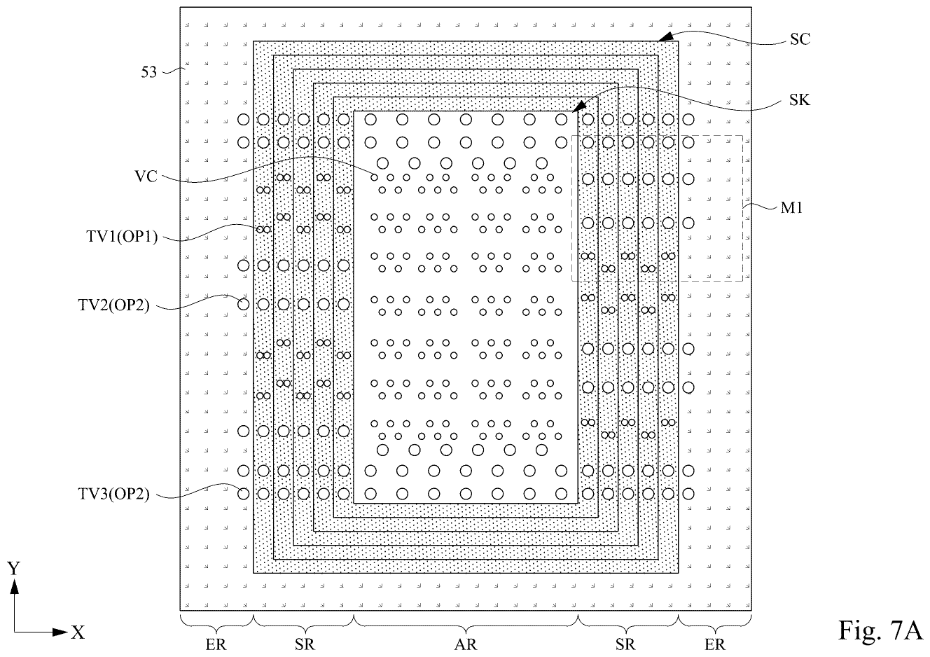

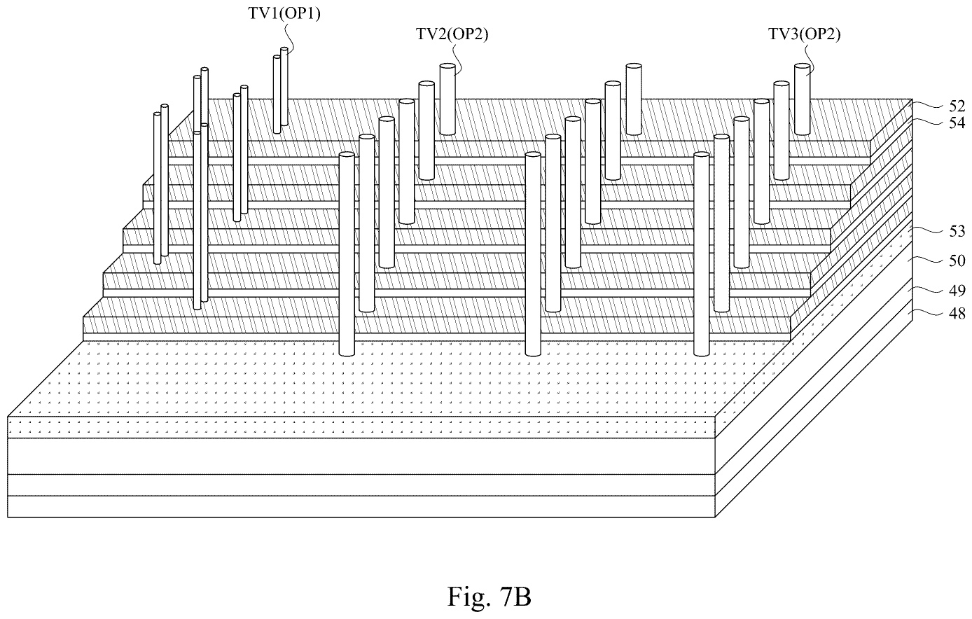

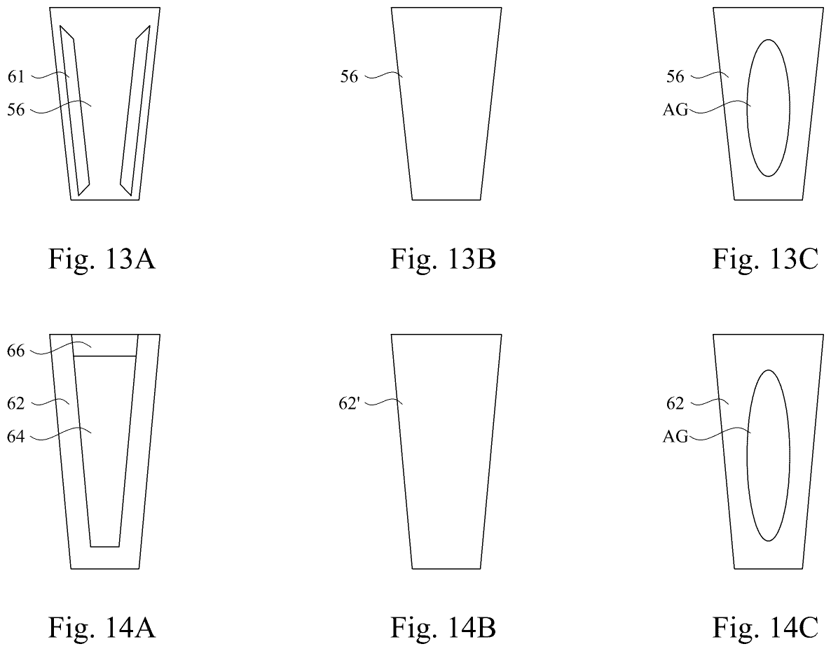

Continue referring to FIG. 6A and FIG. 6B, lithography and etching processes are performed to form the first openings OP1. Subsequently, referring to FIG. 7A and FIG. 7B, lithography and etching processes are performed to form the second openings OP2. The size of the second opening OP2 may be greater than the size of the first opening OP1. Afterwards, an insulating material is filled in the first openings OP1 and the second openings OP2 to form insulating pillars 56 of the through vias TV1, TV2, and TV3. The insulating material may include silicon oxide, as shown in FIG. 13B. It is noted that the through vias TV1 are formed in the first openings OP1, and the through vias TV2 and TV3 are all formed in the second openings OP2. The through vias TV2 and TV3 have substantially same size accordingly.

In some embodiments, the through vias TV1, TV2 and TV3 may include the insulating pillar 56 covering a spacer 61. The spacer 61 is, for example, polysilicon or silicon nitride, as shown in FIG. 13A. In some other embodiments, the through vias TV1 and TV2 may include the insulating pillar 56 covering an air gap AG, without any conductive material, as shown in FIG. 13C.

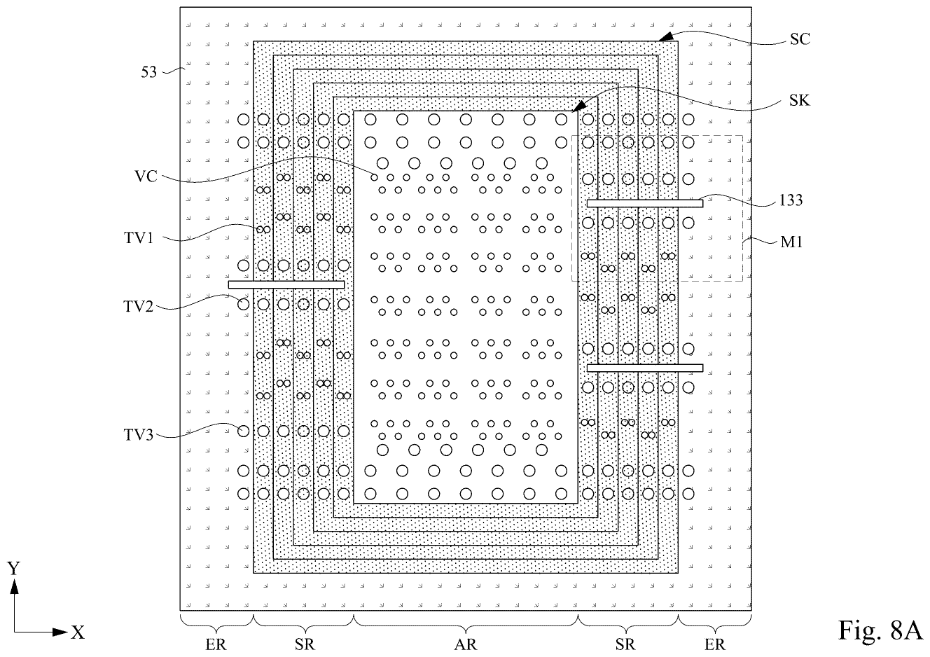

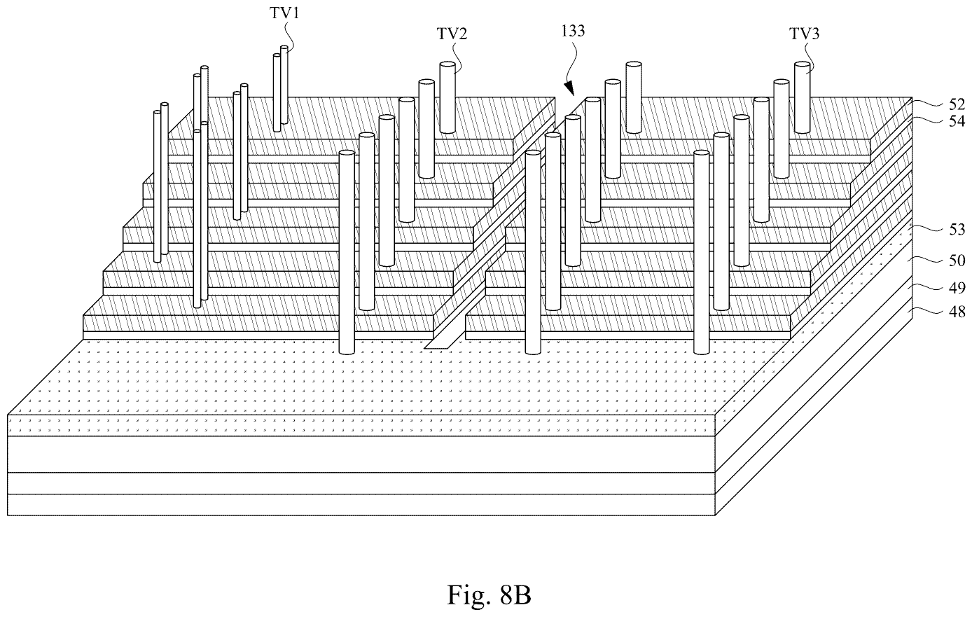

Referring to FIG. 8A and FIG. 8B, the stacked structure SK and the conductive layer 53 are patterned to form multiple slit trenches 133. During the etching process, the dielectric substrate 50 or the conductive layer 53 may serve as an etching stop layer, so that the slit trenches 133 expose the conductive layer 53. In some embodiments, the slit trenches 133 may further expose the dielectric substrate 50. The etching process may include a dry etching process, such as a plasma etching process. The slit trench 133 is formed between two adjacent rows of the through vias TV2.

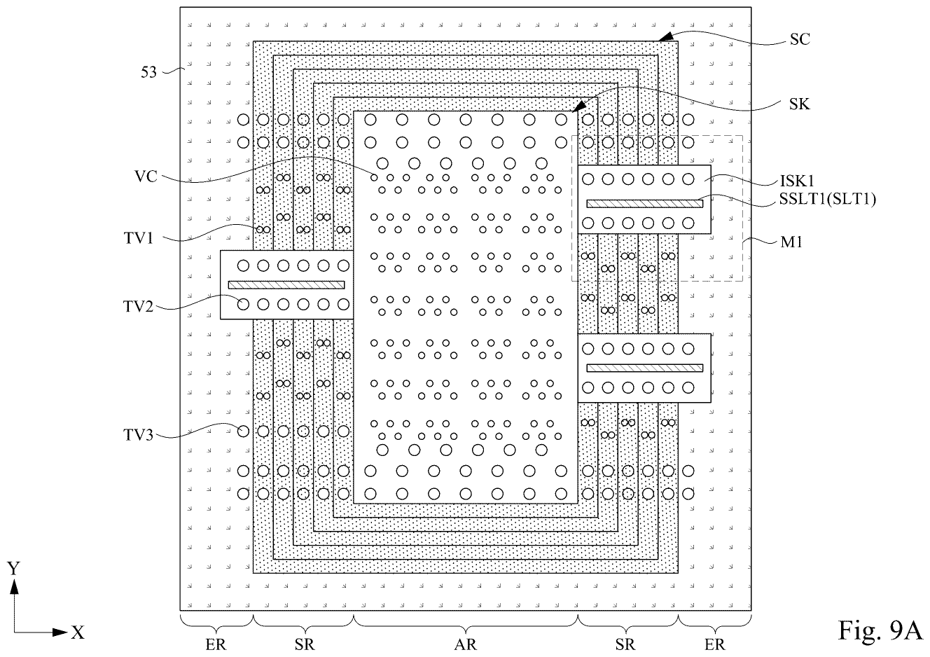

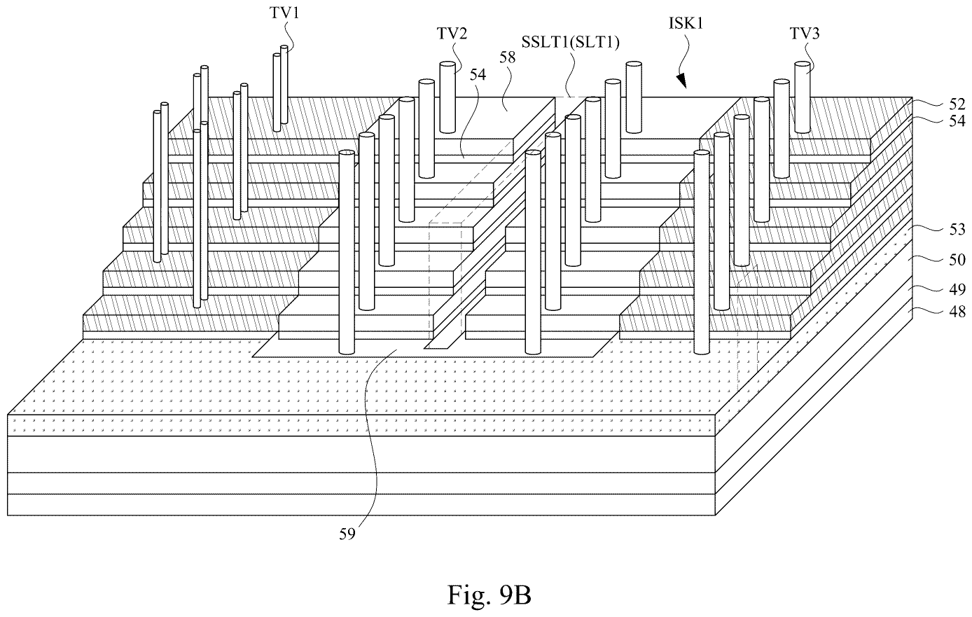

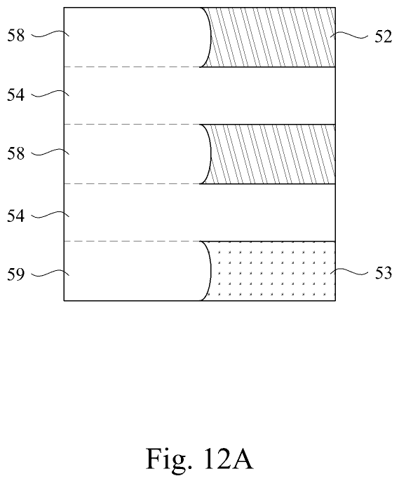

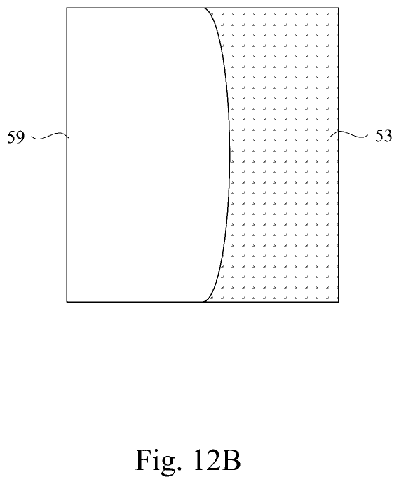

Referring to FIG. 9A and FIG. 9B, a part of the conductive layer 53 is replaced by the insulating layers 59, and a part of the intermediate layers 52 are replaced by the insulating layers 58 through the slit trench 133. As a result, the insulating layer 58 and the insulating layer 54 are stacked alternately to form the insulating stacked structures ISK1, and the insulating layer 59 is formed under the insulating stacked structures ISK1. Insulating stacked structures ISK1 and the insulating layers 59 are formed at the staircase region SR. First, an etching process, such as a wet etching process, is performed to remove a part of the conductive layer 53 and the intermediate layers 52 to form multiple horizontal openings (not shown). When the conductive layer 53 and the intermediate layers 52 are removed from the slit trench 133 using a wet etching process, the etching characteristics cause the removed conductive layer 53 and the intermediate layer 52 to have concave sidewalls. Next, the insulating layers 58 and 59 are deposited in the horizontal openings. The insulating layer 58 is, for example, silicon oxide. The insulating layer 59 is, for example, silicon oxide. After filling the insulating layer 58 and the insulating layer 59, the interfaces between the intermediate layer 52, the conductive layer 53, the insulating layer 58, the insulating layer 59 and the insulating layer 54 can be as shown in FIG. 12A. When the insulating layers 58 and the insulating layer 59 are formed in the horizontal openings, discontinuous voids may naturally form between the insulating layer 58, the insulating layer 59 and the insulating layer 54. These voids may be caused by the filling material not fully sealing with the old material. The voids between the insulating layer 58 and the insulating layer 54, and the voids between the insulating layer 59 and the insulating layer 54 may be arranged in X direction. In addition, since the etched conductive layer 53 and the intermediate layers 52 have concave sidewalls, there is a concave sidewall between the filled insulating layer 59 and the conductive layer 53 toward the conductive layer 53. In addition, there is a concave sidewall between the filled insulating layer 58 and the intermediate layer 52 toward the intermediate layer 52. This embodiment corresponds to the embodiment of FIGS. 3A to 3E.

In some embodiments, only the conductive layer 53 is replaced by the insulating layer 59 through the slit trench 133, and the intermediate layers 52 are not replaced in this step. After filling in the insulating layer 59, the interfaces between the conductive layer 53, the insulating layer 59 and the insulating layer 54 can be as shown in FIG. 12B. Discontinuous voids may naturally form between the insulating layer 59 and the insulating layer 54. In addition, there is a concave sidewall between the filled insulating layer 59 and the conductive layer 53 toward the conductive layer 53. This embodiment corresponds to the embodiment of FIGS. 4A to 4D.

Next, the first sub-slits SSLT1 of the first slits SLT1 are formed in the slit trenches 133. The method of forming the first sub-slits SSLT1 of the first slits SLT1 is described as follows. An insulating liner material and a conductive material are filled on the stacked structure SK and in the slit trenches 133. The insulating liner material may include silicon oxide. The conductive material may include polysilicon. Then, excess insulating liner material and conductive material on the stacked structure SK and the edge region ER are removed through an etching back process or a planarization process, so as to form a liner layer 62 and a conductive layer 64. Afterwards, a dielectric material is formed on the substrate 48, and then an etching back process or a planarization process may be performed to planarize the dielectric material to form a dielectric layer 66. The liner layer 62, the conductive layer 64 and a part of the dielectric layer 66 form a first sub-slits SSLT1 of the first slit SLT1, as shown in FIG. 14A.

In some embodiments, the first slit SLT1 may also be completely filled with an insulating material 62′, without any conductive material, as shown in FIG. 14B. In some other embodiments, the first slit SLT1 may include a liner layer 62 covering an air gap AG, without any conductive material, as shown in FIG. 14C.

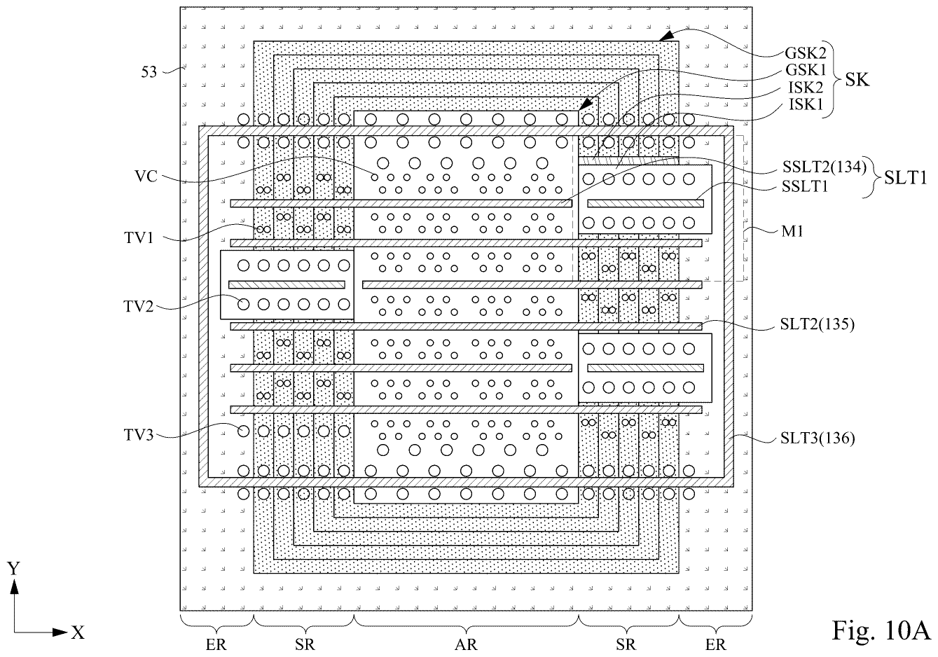

Referring to FIG. 10A and FIG. 10B, the stacked structure SK and the conductive layer 53 are patterned to form multiple slit trenches 134, slit trenches 135, and a slit trench 136. The formation of the slit trenches 134, slit trenches 135, and the slit trench 136 is similar to the formation of the slit trenches 133. The difference is that the slit trench 134 is formed extending from over the memory array region AR to over the staircase region SR and the edge region ER in X direction, the slit trench 134 is aligned with the first sub-slits SSLT1 of the first slits SLT1 in Y direction, the slit trench 135 is between the slit trench 134 and the first sub-slits SSLT1 of the first slits SLT1 arranged in Y direction, and the slit trench 136 is formed on the periphery of the slit trenches 134, the slit trenches 135, and the first sub-slits SSLT1 of the first slits SLT1. The sidewalls of the slit trenches 134, the slit trenches 135, and the slit trench 136 expose the intermediate layers 52 and the insulating layers 54, but the sidewalls of the slit trenches 134, the slit trenches 135, and the slit trench 136 do not expose the first sub-slits SSLT1 of the first slits SLT1.

Next, a replacement process is performed to the intermediate layers 52. First, an etching process such as a wet etching process is performed to remove a part of the intermediate layers 52 through the slit trenches 134, the slit trenches 135, and the slit trench 136 to form multiple horizontal openings (not shown). Multiple charge storage layers 12, multiple blocking layers 36 and multiple gate layers 38 are respectively formed in multiple horizontal openings. For clarity, multiple charge storage layers 12, multiple blocking layers 36 and multiple gate layers 38 are not shown in FIG. 10A and FIG. 10B. The charge storage layers 12 may include silicon nitride. The blocking layers 36 may include a material having a high dielectric constant greater than or equal to 7, such as aluminum oxide (Al₂O₃), hafnium oxide (HfO₂), lanthanum oxide (La₂O₅), transition metal oxide, lanthanide oxide or a combination thereof. The gate layers 38 may include tungsten. In some embodiments, multiple blocking layers (not shown) are also formed prior to the formation of the gate layers 38. The material of the blocking layers may include titanium (Ti), titanium nitride (TiN), tantalum (Ta), tantalum nitride (TaN) or a combination thereof.

The method of forming the charge storage layer 12, the blocking layer 36, the blocking layer and the gate layer 38 includes sequentially forming a storage material, a blocking material, a blocking material and a conductive material in the slit trenches 134, the slit trenches 135, the slit trench 136, and the horizontal openings. Then, an etching back process is performed to remove the storage material, the blocking material, the blocking material and the conductive material in the slit trenches 134, the slit trenches 135, and the slit trench 136. The tunneling layer 14, the charge storage layer 12 and the blocking layer 36 are collectively referred to as a charge storage structure 40 (as shown in FIG. 1C). The gate stacked structure GSK1 and GSK2 are thus formed. The gate stacked structure GSK1 is disposed over the memory array region AR of the substrate 48, the gate stacked structure GSK2 is disposed over the staircase region SR of the substrate 48, and the gate stacked structure GSK1 and GSK2 include multiple gate layers 38 and multiple insulating layers 54 stacked alternately.

Afterwards, the second sub-slits SSLT2 of the first slits SLT1 are formed in the slit trenches 134, the second slits SLT2 are formed in the slit trench 135, and the third slit SLT3 is formed in the slit trench 136, as shown in FIGS. 14A to 14C. The formation of the second sub-slits SSLT2 of the first slits SLT1, the second slits SLT2 and the third slit SLT3 is similar to the formation of the first sub-slits SSLT1 of the first slits SLT1. The spacer is between the resulting first sub-slits SSLT1 of the first slits SLT1 and the resulting second sub-slits SSLT2 of the first slits SLT1 (as shown in FIG. 3E or FIG. 4D).

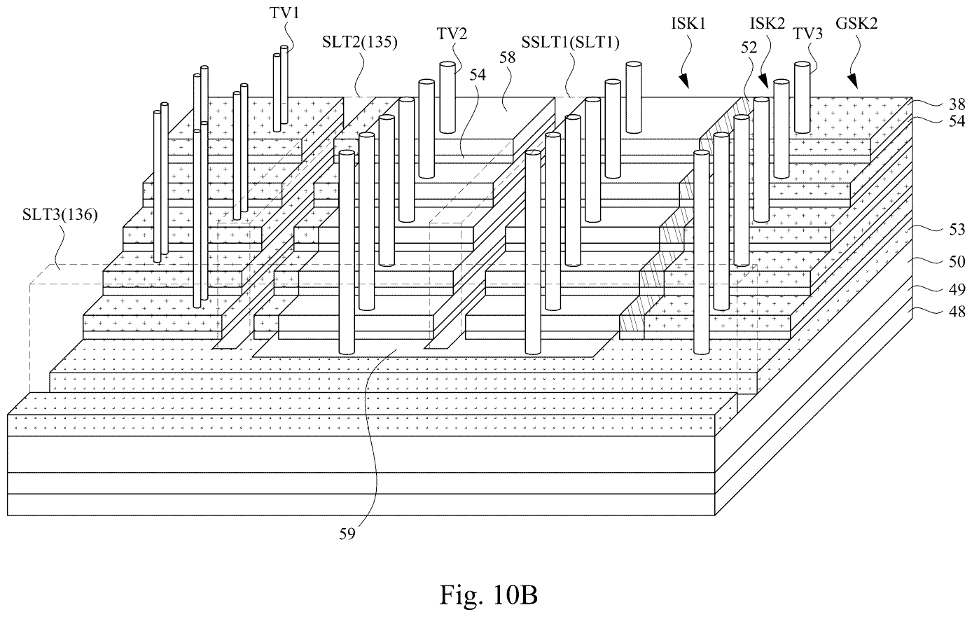

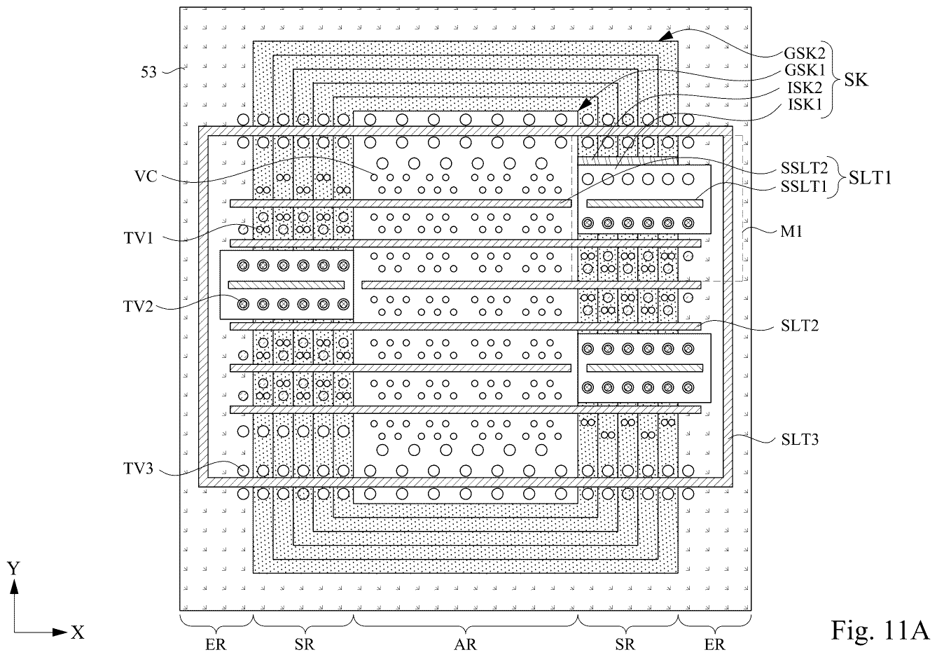

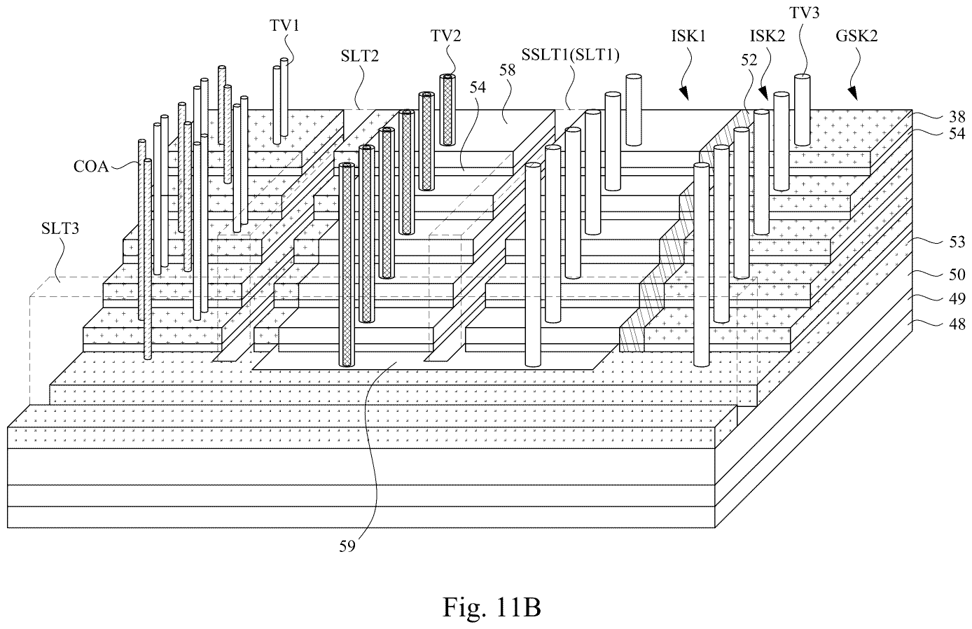

Referring to FIG. 11A and FIG. 11B, conductive vias 57 are formed in some of the insulating pillars 56 of the through vias TV2, and contacts COA are formed. As shown in FIG. 3C or FIG. 4C, the conductive vias 57 are located in the insulating pillars 56 of the through vias TV2 and extend through the insulating pillars 56 and the dielectric substrate 50, landed on and electrically connected to the topmost conductive layer TM of the interconnection structure 49. The contacts COA are landed on the gate layers 38. The method for forming the conductive vias 57 includes performing lithography and etching processes to form multiple third openings (not shown) in the insulating pillars 56 of the through vias TV2. The third openings penetrate through the insulating pillars 56 and the dielectric substrate 50, exposing the topmost conductive layer TM of the interconnection structure 49. Next, a conductive material is formed on the substrate 48, and the conductive material is filled in the third openings. The conductive material may include tungsten or polysilicon. Afterwards, a planarization process such as a chemical mechanical polishing process is performed to remove the conductive material outside the via holes. The contacts COA can be formed by a method similar to that of the conductive via 57 or any known method. It is noted that the conductive vias 57 are only formed in the insulating pillars 56 of the through vias TV2, and are not formed in the insulating pillars 56 of the through vias TV3. The through vias TV3 still remain as the insulating vias accordingly.

In addition to being used in 3D AND flash memory, the present disclosure can also be used in 3D NOR flash memory and 3D NAND flash memory.

As mentioned above, in the present disclosure, in order to avoid the leakage current between the through via, the conductive layer and the gate layers, a first slit for forming the insulating layers replacing the gate layers and the conductive layer is formed. The through via and the gate layers of the staircase structure, and the through via and the conductive layer are separated by the insulating layers respectively. This can reduce the probability of leakage current between the through via and the conductive layer and the gate layers.

What is claimed is:

1. A memory device comprising:
a substrate having a memory array region and a staircase region;
a stacked structure comprising a first gate stacked structure, and a plurality of second gate stacked structures, the first gate stacked structure located over the memory array region, the plurality of second gate stacked structures located over the staircase region, wherein the first gate stacked structure and the plurality of second gate stacked structures comprise a plurality of gate layers and a plurality of first insulating layers stacked alternately; and
a plurality of first slits and a plurality second slits arranged alternatively in a first direction and extending in a second direction, wherein
each of the plurality of first slits comprise a first sub-slit and a second sub-slit, the first sub-slit extends over the staircase region, and the second sub-slit extends over the memory array region, and a spacer is between the first sub-slit and the second sub-slit,
the plurality of second slits extending from over the memory array region to over the staircase region.

2. The memory device of claim 1, wherein the stacked structure further comprises a plurality of insulating stacked structures, and the plurality of second gate stacked structures and the plurality of insulating stacked structures are arranged in the first direction alternately at the staircase region, and the spacer has an interface between the first gate stacked structure and one of the plurality of insulating stacked structures.

3. The memory device of claim 2, wherein the plurality of insulating stacked structures comprises a plurality of second insulating layers and the plurality of first insulating layers stacked alternately, the plurality of second insulating layers are adjacent to the plurality of gate layers, and the plurality of first insulating layers extend from the plurality of second gate stacked structures to the plurality of insulating stacked structures, and a plurality of voids are between the plurality of second insulating layers and the plurality of first insulating layers, and the plurality of voids are arranged in the second direction.

4. The memory device of claim 2, further comprising:
a conductive layer between the first gate stacked structure and the substrate; and
a third insulating layer between one of the plurality of insulating stacked structures and the substrate, wherein the spacer further has an interface between the conductive layer and the third insulating layer.

5. The memory device of claim 2, further comprising:
an interconnection structure over the staircase region; and
a plurality of through vias arranged over the staircase region and are electrically connected to the interconnection structure, and the plurality of through vias are surrounded by one of the plurality of insulating stacked structures.

6. The memory device of claim 1, wherein each of the plurality of through vias comprises an insulating pillar and a conductive via, and the conductive via penetrates through the insulating pillar.

7. The memory device of claim 5, wherein each of the plurality of through vias comprises an insulating pillar and a conductive via, and the conductive via is in contact with one of the plurality of insulating stacked structures.

8. The memory device of claim 1, further comprising:
a plurality of contacts arranged over the staircase region and is surrounded by one of the plurality of second gate stacked structures.

9. The memory device of claim 1, further comprising:
a conductive layer between the first gate stacked structure and the substrate; and
a third insulating layer between one of the plurality of second gate stacked structures and the substrate, wherein the spacer further has an interface between the conductive layer and the third insulating layer.

10. The memory device of claim 9, further comprising:
an interconnection structure over the staircase region; and
a plurality of through vias arranged over the staircase region and are electrically connected to the interconnection structure, and the plurality of through vias are surrounded by the third insulating layer.

11. A manufacturing method of forming memory device comprising:
forming a stacked structure over a substrate having a memory array region and a staircase region, wherein the stacked structure comprises a plurality of intermediate layers and a plurality of first insulating layers stacked alternately, and the stacked structure has a staircase structure over the staircase region;
forming a first slit trench in the stacked structure over the staircase region;
forming a first sub-slit of a first slit in the first slit trench;
forming a second slit trench in the stacked structure aligned with the first sub-slit of the first slit in a first direction, and the second slit trench extending from over the memory array region to over the staircase region in a second direction;
replacing the plurality of intermediate layers by a plurality of gate layers through the second slit trench to form a first gate stacked structure over the memory array region and a second gate stacked structure over the staircase region; and
forming a second sub-slit of the first slit in the second slit trench, wherein the first sub-slit and the second sub-slit are separated by a spacer.

12. The manufacturing method of claim 11, further comprising:
forming a conductive layer over the substrate before forming the stacked structure, wherein the conductive layer is exposed after forming the first slit trench; and
replacing a portion of the conductive layer by a second insulating layer through the first slit trench.

13. The manufacturing method of claim 12, wherein a concave sidewall is formed between the conductive layer and the second insulating layer toward the conductive layer.

14. The manufacturing method of claim 12, wherein the spacer has an interface between the conductive layer and the second insulating layer.

15. The manufacturing method of claim 12, further comprising:
forming a plurality of through vias surrounded by the second insulating layer.

16. The manufacturing method of claim 11, further comprising:
replacing the plurality of intermediate layers by a plurality of third insulating layers through the first slit trench to form an insulating stacked structure after the first slit trench is formed.

17. The manufacturing method of claim 16, wherein the spacer has an interface between the first gate stacked structure and the insulating stacked structure.

18. The manufacturing method of claim 16, wherein a plurality of concave sidewalls are formed between the plurality of third insulating layers and the plurality of intermediate layers toward the plurality of intermediate layers.

19. The manufacturing method of claim 16, further comprising:
forming a plurality of through vias surrounded by the insulating stacked structure; and
forming a plurality of contacts surrounded by the second gate stacked structure.

20. The manufacturing method of claim 19, wherein each of the plurality of through vias comprises an insulating pillar and a conductive via, and the conductive via is in contact with the insulating stacked structure.
